(19) United States
(12) Patent Application Publication
(10) Pub. No.: US 2007/0251456 A1
(43) Pub. Date: Nov. 1, 2007

(54) Composite heater and chill plate

(75) Inventors: Harald Herchen, Los Altos, CA (US); Sharathchandra Somayaji, Sunnyvale, CA (US); Tetsuya Ishikawa, Saratoga, CA (US); Brian C. Lue, Mountain View, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: APPLIED MATERIALS, INC., A Delaware corporation, Santa Clara, CA (US)

(21) Appl. No.: 11/414,730

(22) Filed: Apr. 27, 2006

(51) Int. Cl. C23C 16/00

(52) U.S. Cl. 118/724

(57) ABSTRACT

An integrated system for baking and chilling wafers includes a heater for heating a wafer to an elevated temperature, a chiller for cooling the wafer, and a shuttle operatively connected to the heater and the chiller for transferring the wafer between the heater and the chiller. The chiller further includes a low thermal mass wafer support for providing support to a bottom surface of a wafer and a chill plate coupled to the low thermal mass wafer support for cooling the wafer. The low thermal mass wafer support has a higher thermal conductivity in the plane parallel to the bottom surface of the wafer than in the direction perpendicular to the bottom surface of the wafer. The low thermal mass wafer support can further include a plurality of proximity pins for supporting the wafer.

### BACKGROUND OF THE INVENTION

The present invention relates generally to the field of substrate processing equipment. More particularly, the present invention relates to a method and apparatus for controlling the temperature of substrates, such as semiconductor substrates, used in the formation of integrated circuits.

Modern integrated circuits contain millions of individual elements that are formed by patterning the materials, such as silicon, metal and/or dielectric layers, that make up the integrated circuit to sizes that are small fractions of a micrometer. The technique used throughout the industry for forming such patterns is photolithography. A typical photolithography process sequence generally includes depositing one or more uniform photoresist (resist) layers on the surface of a substrate, drying and curing the deposited layers, patterning the substrate by exposing the photoresist layer to electromagnetic radiation that is suitable for modifying the exposed layer and then developing the patterned photoresist layer.

It is common in the semiconductor industry for many of the steps associated with the photolithography process to be performed in a multi-chamber processing system (e.g., a cluster tool) that has the capability to sequentially process semiconductor wafers in a controlled manner. One example of a cluster tool that is used to deposit (i.e., coat) and develop a photoresist material is commonly referred to as a track lithography tool.

Track lithography tools typically include a mainframe that houses multiple chambers (which are sometimes referred to herein as stations) dedicated to performing the various tasks associated with pre- and post-lithography processing. There are typically both wet and dry processing chambers within track lithography tools. Wet chambers include coat and/or develop bowls, while dry chambers include thermal control units that house bake and/or chill plates. Track lithography tools also frequently include one or more pod/cassette mounting devices, such as an industry standard FOUP (front opening unified pod), to receive substrates from and return substrates to the clean room, multiple substrate transfer robots to transfer substrates between the various chambers/stations of the track tool and an interface that allows the tool to be operatively coupled to a lithography exposure tool in order to transfer substrates into the exposure tool and receive substrates from the exposure tool after the substrates are processed within the exposure tool.

Over the years there has been a strong push within the semiconductor industry to increase throughput of wafers in semiconductor processing tools while at the same time increasing yields of semiconductor devices in wafers. The reduced feature sizes have caused the industry's tolerance to shrink, which in turn, has resulted in semiconductor manufacturing specifications having more stringent requirements for process uniformity and repeatability. An important factor in improving the throughput of semiconductor processing tools while at the same time increasing yields across wafers, is the ability to reliably, quickly and consistently achieve and maintain uniform process conditions, such as temperature, across the entire wafer. Those skilled in the art will recognize that processing a wafer when there are temperature differences across the wafer can reduce yields.

Track lithography tools include heaters and chillers which heat or cool wafers to an optimum processing temperature before the wafers are processed. Although sophisticated heater and chiller assemblies are used to heat and cool wafers, they are unable to meet today's stringent requirements for rapid uniform heating and cooling of wafers. Since many heater and chiller assemblies do not provide sufficiently uniform cooling and/or heating of wafers, the throughput of semiconductor processing tools that use heater and chiller assemblies is reduced because a wait time is built into the process to allow the temperature of the wafer to reach equilibrium. The non-uniform heating and cooling of wafers causes either a reduction in throughput because the process must be delayed until temperature uniformity is achieved or a reduction in yields if the wafer is processed before the temperature across the entire wafer is substantially uniform. One cause of the non-uniform heating and cooling is the limitation to how flat the wafer support can be made. Another cause in the non-uniform cooling or heating of the wafer is the variation in the air gap from the heater or chill plate to the wafer.

Therefore what is needed is a system that uniformly heats and cools a wafer, thereby making the heating and cooling process more efficient.

### SUMMARY OF THE INVENTION

According to the present invention, methods and apparatus related to semiconductor manufacturing equipment are provided. More particularly, embodiments of the present invention relate to a method and apparatus for heating and/or cooling a substrate in a highly controllable manner. Embodiments of the invention contemplate multiple substrates being processed according to the same heating and cooling sequence in a highly controllable manner, thus helping to ensure a consistent wafer temperature for each substrate. While some embodiments of the invention are particularly useful in heating and/or cooling substrates in a chamber or station of a track lithography tool, other embodiments of the invention can be used in other applications where it is desirable to heat and cool substrates in a highly controllable manner.

In an embodiment of the present invention, a system for chilling wafers includes a low thermal mass wafer support for providing support to a bottom surface of a wafer and a chill plate coupled to the low thermal mass wafer support for cooling the wafer. The low thermal mass wafer support has a higher thermal conductivity in the plane parallel to the bottom surface of the wafer than in the direction perpendicular to the bottom surface of the wafer. In one embodiment the thermal conductivity of the low thermal mass wafer support can be ten times greater in the plane parallel to the bottom surface of the wafer than in the direction perpendicular to the bottom surface of the wafer. In another embodiment, the thermal conductivity of the low thermal mass wafer support is one hundred times greater in the plane parallel to the bottom surface of the wafer than in the direction perpendicular to the bottom surface of the wafer.

In another embodiment of the invention, the low thermal mass wafer support is made of a carbon composite.

In yet another embodiment of the invention, the low thermal mass wafer support is a heat pipe containing fluid.

In yet another embodiment of the invention, the low thermal mass wafer support has a thickness of less than 2 mm. In some applications the thickness of the low thermal mass wafer support is less than 1.2 mm.

In yet another embodiment of the invention, the low thermal mass wafer support has a coefficient of thermal expansion that is less than the coefficient of thermal expansion of the wafer.

In another embodiment of the present invention, the low thermal mass wafer support is in intermittent or user selectable direct contact with the chill plate. Alternatively, and in a different embodiment, support pins are used to separate the low thermal mass wafer support from the chill plate. When support pins are used, an exchange gas can also be used to provide a thermal link between the low thermal wafer support and the chill plate.

In an additional embodiment of the present invention, a system for chilling wafers includes a low thermal mass wafer support for providing support to a bottom surface of a wafer and a chill plate coupled to the low thermal mass wafer support for cooling the wafer. The low thermal mass wafer support has a higher thermal conductivity in the plane parallel to the bottom surface of the wafer than in the direction perpendicular to the bottom surface of the wafer, and the low thermal mass wafer support further includes a plurality of proximity pins for supporting the wafer.

In another embodiment of the invention, the proximity pins protrude about 30 to 100 microns above a surface of the low thermal mass wafer support. In other embodiments, the proximity pins protrude about 30 to 70 microns above a surface of the low thermal mass wafer support.

In another embodiment of the present invention, the proximity pins are spheres that are partially embedded in the low thermal mass wafer support. The proximity pins can be hard spheres made out of materials such as sapphire.

In yet another embodiment of the present invention, the proximity pins are uniformly distributed over the surface of the low thermal mass wafer support. The proximity pins can be dispersed randomly throughout the low thermal mass wafer support or according to a fixed pattern such a grid pattern, striped pattern or circular pattern.

In yet another embodiment of the present invention, the plurality of proximity pins is at least three.

In an additional embodiment of the present invention, a system for chilling wafers includes a chill plate for cooling a wafer, a low thermal mass wafer support for supporting the wafer while the wafer is cooled with the chill plate, the low thermal wafer support further comprising at least one resistive element to heat the wafer and to provide an electrostatic force to the wafer during heating, and a bendable support positioned between the low thermal mass wafer support and the chill plate for regulating motion generated by activation of the electrostatic chuck. The low thermal mass wafer support has a higher thermal conductivity in the plane parallel to the bottom surface of the wafer than in the direction perpendicular to the bottom surface of the wafer. The low thermal mass wafer support can further include a plurality of proximity pins for supporting the wafer.

In yet another embodiment of the present invention, an integrated system for baking and chilling wafers includes a heater for heating a wafer to an elevated temperature, a chiller for cooling the wafer, and a shuttle operatively connected to the heater and the chiller for transferring wafers between the heater and the chiller. The chiller further includes a low thermal mass wafer support for providing support to a bottom surface of the wafer and a chill plate coupled to the low thermal mass wafer support for cooling the wafer. The low thermal mass wafer support has a higher thermal conductivity in the plane parallel to the bottom surface of the wafer than in the direction perpendicular to the bottom surface of the wafer. The low thermal mass wafer support can further include a plurality of proximity pins for supporting the wafer.

In another embodiment of the present invention, a system for heating wafers includes a low thermal mass wafer support for providing support to a bottom surface of a wafer and a heat plate coupled to the low thermal mass wafer support for heating the wafer. The low thermal mass wafer support has a higher thermal conductivity in the plane parallel to the bottom surface of the wafer than in the direction perpendicular to the bottom surface of the wafer. In one embodiment the thermal conductivity of the low thermal mass wafer support can be ten times greater in the plane parallel to the bottom surface of the wafer than in the direction perpendicular to the bottom surface of the wafer. In another embodiment, the thermal conductivity of the low thermal mass wafer support is one hundred times greater in the plane parallel to the bottom surface of the wafer than in the direction perpendicular to the bottom surface of the wafer.

In another embodiment of the invention, the low thermal mass wafer support used in the heating system is made of a carbon composite.

In yet another embodiment of the invention, the low thermal mass wafer support used in the heating system is a heat pipe containing fluid.

Another embodiment of the invention includes an integrated system for heating and chilling wafers including a heater for heating a wafer to an elevated temperature, a chiller for cooling the wafer, a shuttle operatively connected to the heater and the chiller for transferring the wafer between the heater and the chiller. The chiller further includes a low thermal mass wafer support for providing support to a bottom surface of a wafer and a chill plate coupled to the low thermal mass wafer support for cooling the wafer. The low thermal mass wafer support has a higher thermal conductivity in the plane parallel to the bottom surface of the wafer than in the direction perpendicular to the bottom surface of the wafer. The low mass wafer support can also include a plurality of proximity pins for supporting the wafer.

Another embodiment of the invention includes an integrated system for heating and chilling wafers including a heater for heating a wafer to an elevated temperature, a chiller for cooling the wafer, a shuttle operatively connected to the heater and the chiller for transferring the wafer between the heater and the chiller. The heater further includes a low thermal mass wafer support for providing support to a bottom surface of a wafer and a heat plate coupled to the low thermal mass wafer support for heating the wafer. The low thermal mass wafer support has a higher thermal conductivity in the plane parallel to the bottom surface of the wafer than in the direction perpendicular to the bottom surface of the wafer. The low mass wafer support can also include a plurality of proximity pins for supporting the wafer.

Still another embodiment of the invention includes an integrated system for heating and chilling wafers including a heater for heating a wafer to an elevated temperature, a chiller for cooling the wafer, a shuttle operatively connected to the heater and the chiller for transferring the wafer between the heater and the chiller. The heater further includes a first low thermal mass wafer support for providing support to a bottom surface of a wafer and a heat plate coupled to the first low thermal mass wafer support for supporting the first low thermal mass wafer support and for heating the wafer. The chiller further includes a second low thermal mass wafer support for providing support to a bottom surface of a wafer and a chill plate coupled to the second low thermal mass wafer support for supporting the second low thermal mass wafer support and for cooling the wafer. Both the first and second low thermal mass wafer supports have a higher thermal conductivity in the plane parallel to the bottom surface of the wafer than in the direction perpendicular to the bottom surface of the wafer. In another embodiment the both the first and second low thermal mass wafer supports further include a plurality of proximity pins for supporting the wafer.

### BRIEF DESCRIPTION OF THE DRAWINGS

FIG. 1A is a block diagram illustrating a chiller used to cool wafers in a track lithography tool including a low thermal mass wafer support in accordance with one embodiment of the invention;

FIG. 1B is a block diagram illustrating a cross sectional view of the chiller illustrated in FIG. 1A;

FIG. 2A is a block diagram illustrating another embodiment of a chiller used to cool wafers in a track lithography tool including a low thermal mass wafer support in direct contact with a chill plate;

FIG. 2B is a block diagram illustrating a cross sectional view of the chiller illustrated in FIG. 2A;

FIG. 3 is a block diagram illustrating a cross sectional view of a low thermal mass wafer support with an integrated electrostatic chuck and heater, used to both chill and heat wafers in a track lithography tool;

FIG. 4 is a block diagram illustrating a two zone heater integrated in the low thermal mass wafer support used in a track lithography tool, in accordance with another embodiment of the invention;

FIG. 5 is a block diagram illustrating a cross sectional view of a low thermal mass wafer support thermally separated from a chill plate by compressible or bendable supports in accordance with another embodiment of the invention;

FIG. 6 is a plan view of one embodiment of a track lithography tool incorporating an integrated thermal unit using a low thermal mass wafer support for heating and chilling wafers in accordance with one embodiment of the present invention;

FIG. 7 is a simplified perspective view of integrated thermal unit 605 shown FIG. 6 incorporating the heating and chilling apparatus with the top of the integrated thermal unit removed;

FIG. 8 is a cross-sectional view of heater 607 and chiller 608 of integrated thermal unit 605 shown FIG. 7;

FIG. 9 is a perspective view of shuttle 710 shown FIG. 7, according to one embodiment of the invention;

FIG. 10 is a perspective view of a portion of the integrated thermal unit 605 shown in FIG. 6 having heater 607 and chiller 608 removed;

FIG. 11 is a perspective view of chiller 608 shown in FIG. 6 according to one embodiment of the invention;

FIG. 12 is a perspective view of heater 607 shown in FIG. 6 according to one embodiment of the invention;

FIG. 13 is a perspective view of a cross-section of heater 607 shown in FIG. 12, according to one embodiment of the invention;

FIG. 14 is a cross-sectional view of heater 607 shown in FIGS. 12 and 13, according to one embodiment of the invention;

FIG. 15 is bottom perspective view of heater 607 shown in FIG. 6 according to one embodiment of the invention;

FIG. 16 is a simplified cross-sectional view of an engageable heat sink 1510 shown in FIG. 15;

FIG. 17 is a flowchart illustrating an exemplary sequence of steps used by the track lithography tool shown in FIG. 6 to transport wafers; and

FIG. 18 is a flowchart illustrating an exemplary sequence of processing steps used to run a bottom antireflective coating (BARC) process in the track lithography tool shown in FIG. 6.

### DETAILED DESCRIPTION OF THE INVENTION

Controlling temperature uniformity across a wafer during semiconductor processing can be very useful in producing uniform properties of devices made on wafers. For example, when cooling or heating a wafer during a semiconductor manufacturing process, it can be advantages if the wafer is uniformly cooled or heated so that all portions of the wafer are processed at nearly the same temperature. The present invention provides a system and method for efficiently, rapidly and uniformly cooling or heating a wafer during semiconductor processing. Although the invention is described in terms of cooling or heating wafers in a track lithography tool, the invention can be implemented in tools which cool or heat a wafer during processing. Further details of the track lithography tool configuration can be found in copending U.S. patent application Ser. No. 11/174,681 filed on Jul. 5, 2005 which is hereby incorporated by reference in its entirety.

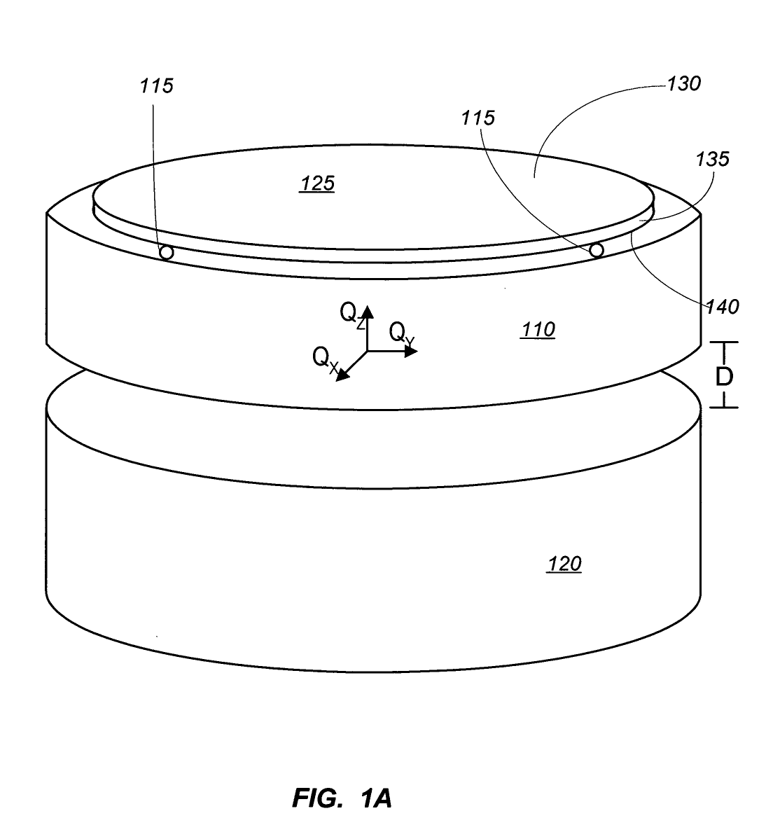

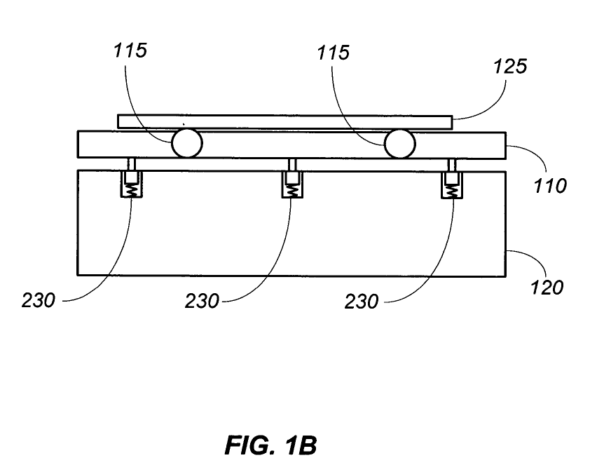

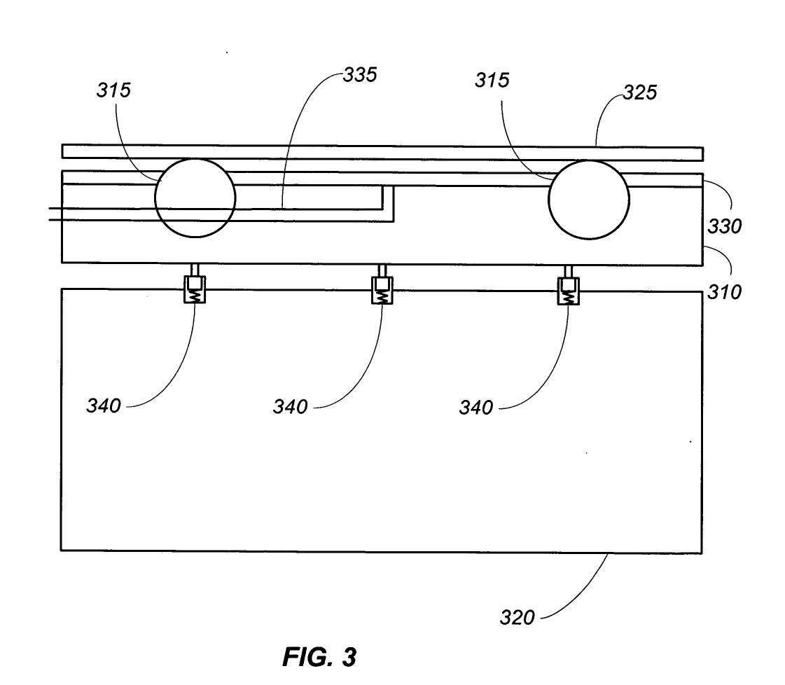

FIG. 1A is a block diagram illustrating a chiller used to cool wafers in a track lithography tool including a low thermal mass wafer support 110, a plurality of proximity pins 115, a chill plate 120, and a wafer 125 having a top surface 130, a bottom surface 135 and side surface 140. The low thermal mass wafer support 110 is spaced a distance D apart from the chill plate 120 by support pins which are not shown in FIG. 1A but is shown in FIG. 1B and is further discussed with reference to FIG. 1B below. Those skilled in the art will also recognize that the distance D can be varied depending on the application. Additionally an exchange gas such as helium or argon, for example, can be used to exchange heat between the low thermal mass wafer support 110 and the chill plate 110. FIG. 1A also illustrates the low thermal mass wafer support 110 thermal conductivity values (Q_{X}, Q_{Y}, and Q_{Z}) along different directions which are specifically selected to be different, as is further discussed below. The proximity pins 115 can be made of hard spheres such as sapphire, which are embedded into the low mass wafer support 110 and are used to support the wafer 125. Moreover the proximity pins 115 are made to protrude about 30 to 100 microns above the surface low thermal mass wafer support 110 as discussed in further detail below with reference to FIG. 3. In one embodiment the proximity pins 115 protrude about 70 microns above the surface of the low mass wafer support 110.

FIG. 1B is a block diagram illustrating a cross sectional view of the chiller illustrated in FIG. 1A including a low thermal mass wafer support 110, a plurality of proximity pins 115, a chill plate 120, and a wafer 125, and a plurality of support pins 230. Wafer 125 contacts proximity pins 115 which are embedded in the low thermal mass wafer support 110. The low thermal mass wafer support 110 is separated from the chill plate 120 by the plurality of support pins 230. In one embodiment the plurality of support pins 230 are very good thermal conductors so that heat is transferred from the low thermal mass wafer support 110 to the chill plate 120 through the support pins. In another embodiment, exchange gas is used to transfer heat between the low mass wafer support 110 and the chill plate 120.

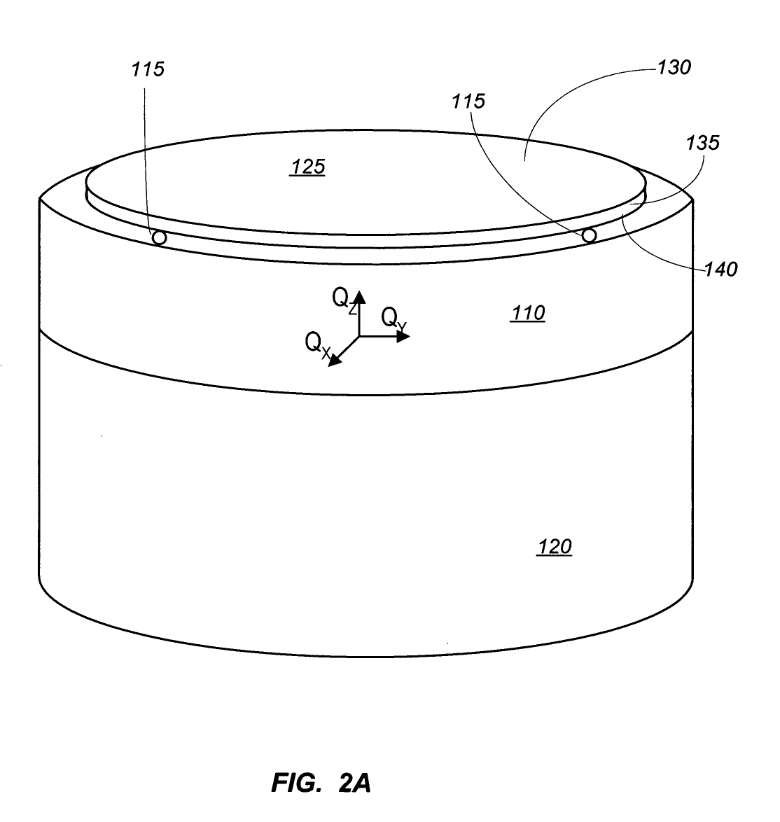

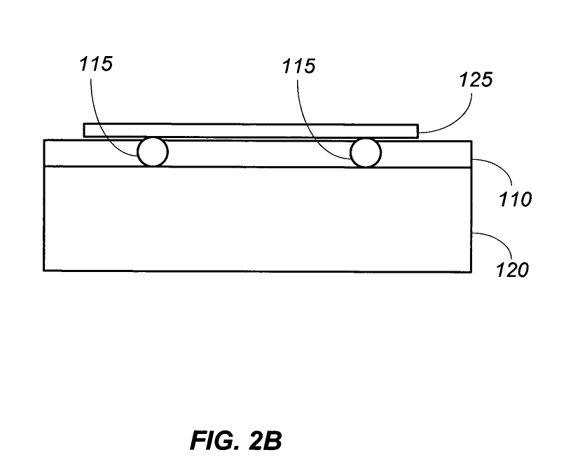

FIG. 2A is a block diagram illustrating another embodiment of the chiller where chill plate 120 is in direct contact with the low mass wafer support including a low thermal mass wafer support 110, a plurality of proximity pins 115, a chill plate 120, and a wafer 125 having a top surface 130, a bottom surface 135 and side surface 140. The chill plate 120 is held in direct contact against the low thermal mass wafer support 110 to provide the cooling. Since the low thermal mass wafer support 110 has an extremely low thermal expansion, rubbing between the chill plate 120 and the low thermal mass wafer support 110 is significantly reduced, which results in reduced particle formation and in reduced wearing of the chill plate while at the same time having the good thermal link between the chill plate 120 and the low thermal mass wafer support 110.

FIG. 2B is a block diagram illustrating a cross sectional view of the chiller illustrated in FIG. 2A including a low thermal mass wafer support 110, a plurality of proximity pins 115, a chill plate 120, and a wafer 125. Wafer 125 contacts proximity pins 115 which are embedded in the low thermal mass wafer support 110. In this embodiment the low thermal mass wafer support 110 is in direct contact with the chill plate 120 so that heat is exchanged directly between the chill plate 120 and the low thermal mass wafer support 110. An exchange gas such as helium or argon can be used to assist with heat transfer.

The low thermal mass wafer support 110 is constructed so that it has a higher thermal conductivity in the plane parallel to the top wafer surface 130 and bottom wafer surface 135 than in the direction perpendicular to the top wafer surface 130 and bottom wafer surface 135. The thermal conductivity is illustrated by the values Q_{X}, Q_{Y}, and Q_{Z}, which represent the thermal conductivity in the x, y, and z directions where the x and y directions define a plane substantially parallel to the top wafer surface 130 and the bottom wafer surface 135, and where the z direction is perpendicular to both the x and y directions as illustrated in FIG. 1A. Since the thermal conductivity of the low thermal mass wafer support 110 is greater in the directions parallel to the top wafer surface 130 and bottom wafer surface 135 than in the direction perpendicular to the top wafer surface 130 and bottom wafer surface 135, the wafer will cool uniformly as heat is transferred from the wafer 125 to the chill plate 120. The Q_{X} and Q_{Y} thermal conductivity values can range anywhere from two times to several hundred times greater than the Q_{Z} thermal conductivity value. In one embodiment the Q_{X} and Q_{Y} thermal conductivity values can be 100 times greater than the Q_{Z} thermal conductivity value. In another embodiment only one of the Q_{X} or Q_{Y} thermal conductivity value, but not both can range anywhere from two times to several hundred times greater than the Q_{Z} thermal conductivity value.

In one embodiment of the invention the low thermal mass wafer support 110 has a thickness of less than 2 mm, and preferably less than 1.2 mm. Additionally, the low thermal mass wafer support 110 is constructed out of materials having high thermal conductivity, extremely low thermal expansion coefficients, high rigidity and toughness. One example of such a material is pyrolytic graphite which has density of 2.18-2.22 cc, a thermal conductivity of 300 W/m-K in the “ab” plane and 3.5 W/m_K in the c direction, a thermal expansion of 0.5×10-6/K in the “ab” plane and 20×10-6 in the c direction. Another example of such a material is carbon composite which is made of a carbon fiber mesh embedded in epoxy. A wafer support made of such a carbon composite with these properties will not warp when subjected to rapid heating or cooling on one side. Additionally, a carbon composite wafer support expands or contracts less than wafers or other materials such as aluminum nitride (AlN), which reduces the possibility of particle formation due to rubbing of two parts.

In another embodiment of the present invention, the low thermal mass wafer support 110 is made of a high thermal conductivity carbon composite. An example of a high thermal conductivity carbon composite is a composite having thermal conductivity such as the carbon composites manufactured by ThermoComposite of Denver, Colo. The thermal conductivity can be as high as six times that of aluminum. The high thermal conductivity of the low mass wafer support reduces the temperature variation across the wafer providing for better wafer temperature control. The low thermal mass wafer support having high thermal conductivity can be used with fewer heater zones because the temperature reaches equilibrium much faster than when a wafer support having a low thermal conductivity is used.

In another embodiment, the low thermal mass wafer support 110 is made of copper coated carbon fiber. The copper coated carbon fibers can be arranged within the low thermal mass wafer support to optimize each of the Q_{X}, Q_{Y}, and Q_{Z} thermal conductivity values. In another embodiment the low thermal mass wafer support can be made of heat pipes containing fluid such as those manufactured by HeatLane Technology of Japan. Other embodiments can include heat pipes containing fluid that undergoes phase transitions from solid to liquid, or liquid to gas, or solid to gas. As discussed above, the high thermal conductivity of the low mass wafer support 110 reduces the temperature variation across the wafer 125 providing for better wafer temperature control. The low thermal mass wafer support 110 having high thermal conductivity can be used with fewer heater zones because the temperature reaches an equilibrium much faster than when a wafer support having a low thermal conductivity is used.

Because the low thermal mass wafer support 110 has high strength and rigidity, the proximity pins 115 can be spaced further apart than usual, in accordance with another embodiment of the present invention. The proximity pins are placed further apart then usual, which permits more uniform spacing between the heater/chiller and the wafer. Normally 22 proximity pins are used, but with the low thermal mass wafer support 110, fewer proximity pins can be used. In one embodiment of the present invention the number or proximity pins is less than 22. In another embodiment of the invention, nine (9) proximity pins are used. Moreover by using the proximity pins to separate the low thermal mass wafer support with the back side of the wafer a warped wafer can be made to have uniform thermal contact with the heater or chill plate with minimum chucking voltage.

The proximity pins 115 can be formed by embedding sapphire or similarly hard spheres in the composite during curing. This technique of forming the proximity pins 115 allows the height of the proximity pin 115 to be controlled by the mold used to form the carbon composite low thermal mass wafer support 110. Since only a small percentage of the sapphire balls extend outside of the carbon composite, the sapphire balls are held in place from all directions by the carbon composite. The technique of inserting the sapphire balls into the composite during curing also eliminates the need for a secondary bonding materials which reduces the number of materials needed to make the low thermal mass wafer support 110 and proximity pin 115 combination. Additionally, the stresses on the composite around the proximity pins 115 are low because the fatigue life of carbon composites over the thermal cycling is very long and the thermal expansion coefficient is small.

FIG. 3 is a block diagram illustrating a cross sectional view of an electrostatic chuck and heater integrated in the low thermal mass wafer support used in a track lithography tool, including a low thermal mass wafer support 310, a plurality of proximity pins 315, a chill plate 320, a wafer 325, an electrostatic chuck and heater 330, electrical leads 335, and a plurality of support pins 340. The electrostatic chuck and heater 330 is located on top of the low thermal mass wafer support 310. Additionally, the electrostatic chuck and heater 330 is a bipolar electrostatic chuck that attracts the wafer 325 to the low thermal mass wafer support 310 and substantially removes any bowing of the incoming wafer 325. The electrical leads 335 of the electrostatic chuck and the heater 330 can be fed through the inner regions while being embedded in the low thermal mass wafer support 310, which reduces the thermal footprint or impact on the thermal uniformity. The electrostatic chuck and heater 330 can be manufactured at the same time as the low thermal mass wafer support 310. For example, if the low thermal mass wafer support 310 is a made of a carbon composite, the electrostatic chuck and heater 330 can be laid over the carbon composite and the electrical leads 335 can be integrated into the low thermal mass wafer support 310 during curing of the carbon composite itself. In one embodiment the plurality of support pins 340 are used to separate the low thermal mass wafer support 310 from the chill plate 320. In another embodiment the support pins 340 are not used and the low mass wafer support 310 is in direct contact with the chill plate 320.

The electrostatic chuck and heater 330 can be made by depositing a thin layer of metal on the low thermal mass wafer support 330. The thin layer of metal can be deposited onto the low thermal mass wafer support 310 using a variety of techniques including sputtering, chemical vapor deposition, ion beam deposition, and plasma enhanced vapor deposition as well as other techniques known in the art. In one embodiment, the thin layer of metal can be deposited onto a composite, which makes up the low thermal mass wafer support 310, after the composite has been molded. In another embodiment, the low thermal mass wafer support 310 can be made conductive by adding an additive to it such as carbon. Once the low thermal mass wafer support 310 has been made electrically conductive, the wafer 325 can be chucked electrically to the chill plate for faster and more uniform cooling.

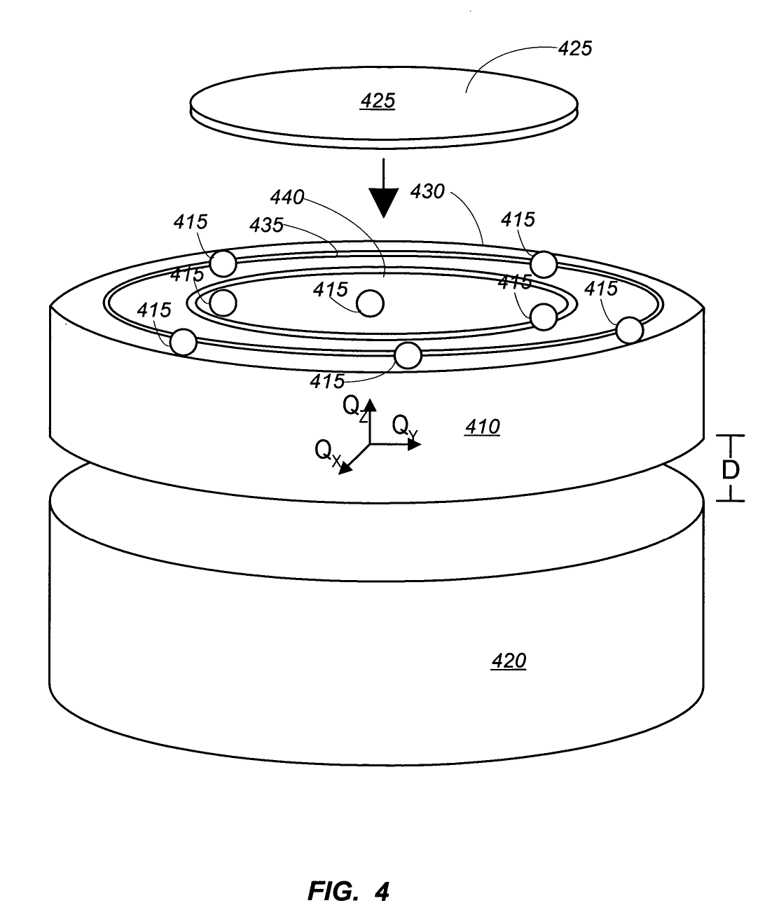

FIG. 4 is a block diagram illustrating a two zone heater integrated in the low thermal mass wafer support used in a track lithography tool, including a low thermal mass wafer support 410, a plurality of proximity pins 415, a chill plate 420, a wafer 425, a two zone heater 430 having a first heater zone 435 and a second heater zone 440. In one embodiment the first heating zone 435 is outside of the outer diameter of the wafer 425 and the second heater zone 440 is located at the periphery of the wafer 425. In this embodiment the thermal footprint extends beyond the wafer and therefore creates excellent temperature uniformity throughout the wafer.

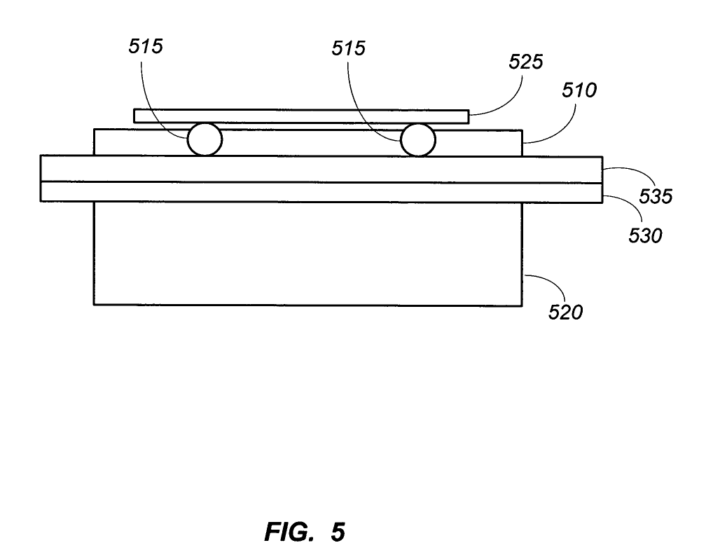

FIG. 5 is a block diagram illustrating a cross section of a low thermal mass wafer support thermally separated from a chill plate by several compressible or bendable supports including a low thermal mass wafer support 510, a plurality of proximity pins 515, a chill plate 520, a wafer 525, a first compressible or bendable support 530, and a second compressible or bendable support 535. Both the first and second compressible or bendable supports 530 and 535 provide particle-free heat transfer, and conform to possibly bending surface above the supports. In one embodiment, the compressible or bendable supports 530 and 535 are made of a gallium indium tin alloy, which is a very good support, with high thermal conductivity and high flexibility. In another embodiment the compressible or bendable supports 530 and 535 are made of low outgassing polymers with boron nitride or carbon nanotubes infiltrated into them, which have a thermal conductivity ranging up to about 6 W/m-K. When the electrostatic chuck is activated causing the wafer support to be attracted to the electrostatic chuck, the supportive force of the flexible supports is overcome providing full thermal contact between the electrostatic chuck and the wafer support for chilling. The compressible or bendable support provide for more compact and reliable motion forming a thermal switch needed to both heat and chill the wafer.

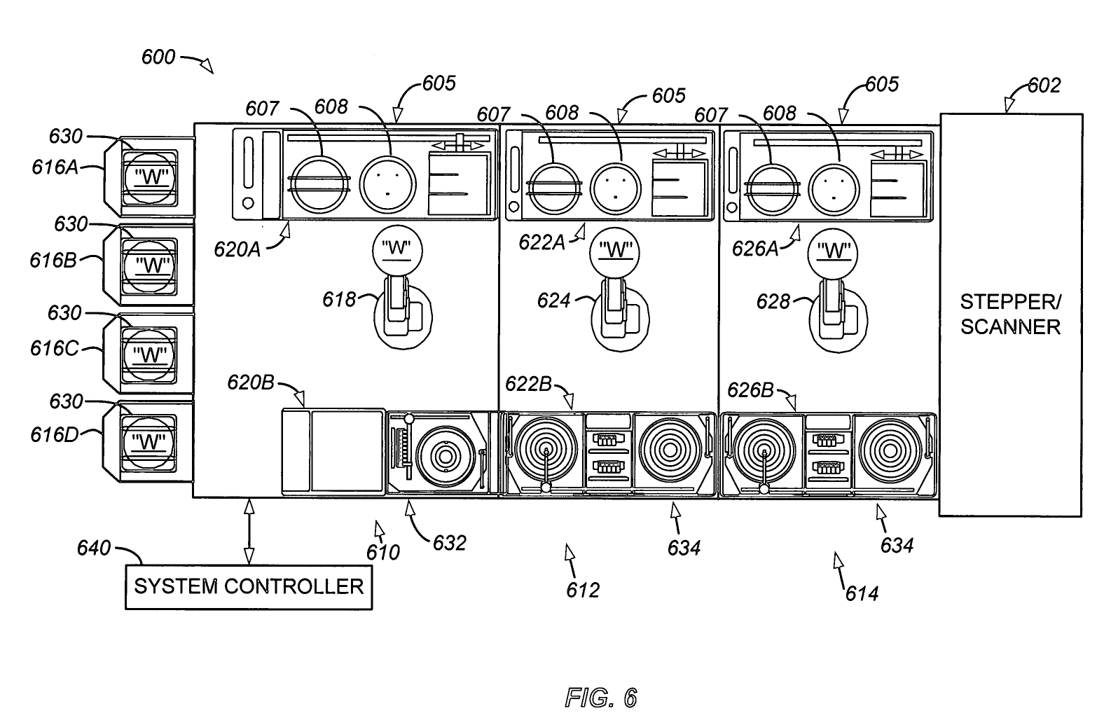

FIG. 6 is a plan view of one embodiment of a track lithography tool 600 in which the embodiments of the present invention may be used. As illustrated in FIG. 6, track lithography 600 contains a front end module 610 (sometimes referred to as a factory interface) 610, a central module 612, and a rear module 614 (sometimes referred to as a scanner interface). Front end module 610 generally contains one or more pod assemblies or FOUPS (e.g., items 616A-D), a front end robot 618, and front end processing racks 620A, 620B. The one or more pod assemblies 616A-D are generally adapted to accept one or more cassettes 630 that may contain one or more substrates “W”, or wafers, that are to be processed in track lithography tool 600.

Central module 612 generally contains a first central processing rack 622A, a second central processing rack 622B, and a central robot 624. Rear module 614 generally contains first and second rear processing racks 626A, 626B and a back end robot 628. Front end robot 618 is adapted to access processing modules in front end processing racks 620A, 620B; central robot 624 is adapted to access processing modules in front end processing racks 620A, 620B, first central processing rack 622A, second central processing rack 622B and/or rear processing racks 626A, 626B; and back end robot 628 is adapted to access processing modules in the rear processing racks 626A, 626B and in some cases exchange substrates with a stepper/scanner 602.

The stepper/scanner 602, which may be purchased from Canon USA, Inc. of San Jose, Calif., Nikon Precision Inc. of Belmont, Calif., or ASML US, Inc. of Tempe, Ariz., is a lithographic projection apparatus used, for example, in the manufacture of integrated circuits (ICs). The scanner/stepper tool 602 exposes a photosensitive material (resist), deposited on the substrate in the cluster tool, to some form of electromagnetic radiation to generate a circuit pattern corresponding to an individual layer of the integrated circuit (IC) device to be formed on the substrate surface.

Each of the processing racks 620A, 620B; 622A, 622B and 626A, 626B contains multiple processing modules in a vertically stacked arrangement. That is, each of the processing racks may contain multiple stacked integrated thermal units 605, multiple stacked coater modules 632, multiple stacked coater/developer modules with shared dispense 634 or other modules that are adapted to perform the various processing steps required of a track photolithography tool. As examples, coater modules 632 may deposit a bottom antireflective coating (BARC); coater/developer modules 634 may be used to deposit and/or develop photoresist layers and integrated thermal units 605 may perform bake and chill operations associated with hardening BARC and/or photoresist layers.

In one embodiment, a system controller 640 is used to control all of the components and processes performed in the cluster tool 600. The controller 640 is generally adapted to communicate with the stepper/scanner 602, monitor and control aspects of the processes performed in the cluster tool 600, and is adapted to control all aspects of the complete substrate processing sequence. In some instances, controller 640 works in conjunction with other controllers, such as controllers not shown, which control the heater 607 and chiller 608 of integrated thermal unit 605, to control certain aspects of the processing sequence. In one embodiment of the invention, the heater 607 and chillers 608 described above with reference to FIGS. 1-5 are the heater and chiller in integrated thermal unit 605. The controller 640, which is typically a microprocessor-based controller, is configured to receive inputs from a user and/or various sensors in one of the processing chambers and appropriately control the processing chamber components in accordance with the various inputs and software instructions retained in the controller's memory. The controller 640 generally contains memory and a CPU (not shown) which are utilized by the controller to retain various programs, process the programs, and execute the programs when necessary. The memory (not shown) is connected to the CPU, and may be one or more of a readily available memory, such as random access memory (RAM), read only memory (ROM), floppy disk, hard disk, or any other form of digital storage, local or remote. Software instructions and data can be coded and stored within the memory for instructing the CPU. The support circuits (not shown) are also connected to the CPU for supporting the processor in a conventional manner. The support circuits may include cache, power supplies, clock circuits, input/output circuitry, subsystems, and the like all well known in the art. A program (or computer instructions) readable by the controller 640 determines which tasks are performable in the processing chamber(s). Preferably, the program is software readable by the controller 640 and includes instructions to monitor and control the process based on defined rules and input data.

It is to be understood that embodiments of the invention are not limited to use with a track lithography tool such as that depicted in FIG. 6. Instead, embodiments of the invention may be used in any track lithography tool including the many different tool configurations described in U.S. application Ser. No. 11/112,281 entitled “Cluster Tool Architecture for Processing a Substrate” filed on Apr. 22, 2005, which is hereby incorporated by reference for all purposes and including configurations not described in the Ser. No. 11/112,281 application.

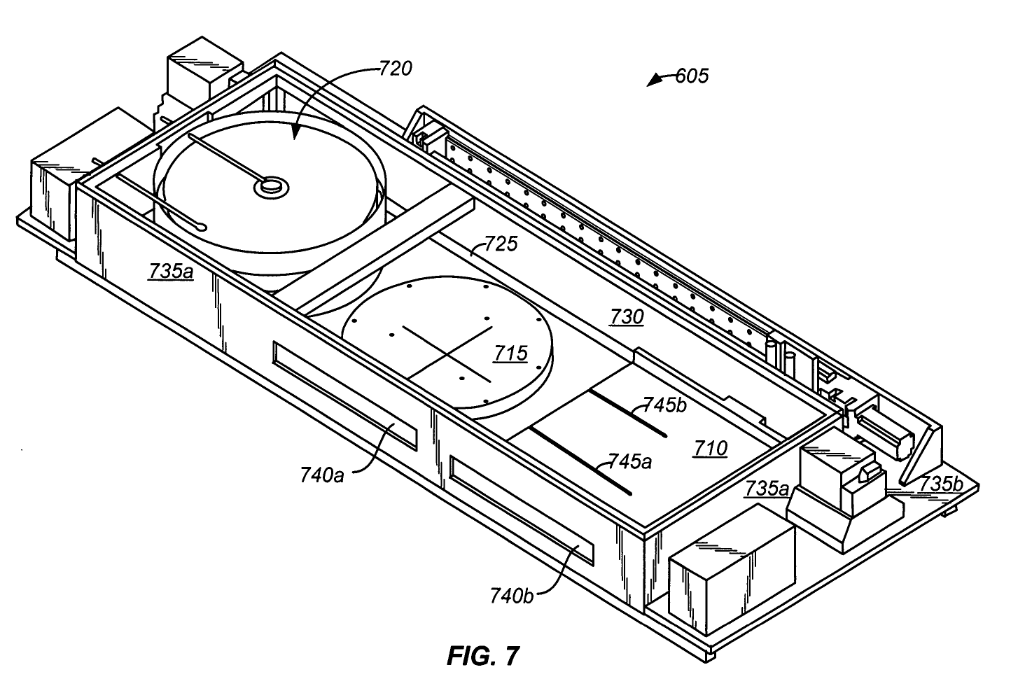

FIG. 7 is a simplified perspective view of integrated thermal unit 605 as seen with its top and particle shield removed. In FIG. 7, shuttle 710, chill plate 715 of the chiller and clam shell enclosure 720 of the heater are shown. Housing 735 includes a side housing 735a, a top housing 735b and a bottom housing 735c. Also visible is a space 725 between rear support piece 730 of housing 735 and bottom piece 735b. Space 725, extends along much of the length of integrated thermal unit 605 to allow shuttle 710 to transfer wafers between other stations. The integrated thermal unit 605 further includes a first transfer slot 740a and a second transfer slot 740b. Both the first transfer slot 740a and the second transfer slot 740b can be used for either introducing wafers into the integrated thermal unit 605 or for removing wafers from the integrated thermal unit 605. Additionally, both first transfer slot 740a and the second transfer slot 740b can have isolation doors to isolate the interior of the integrated thermal unit 605 from the rest of the lithography tool. Slots 745a and 745b are cut into shuttle 710 so that lift pins (not shown) can extend through slots 745a and 745b and support a wafer during transfer of the wafer to and from the shuttle 710.

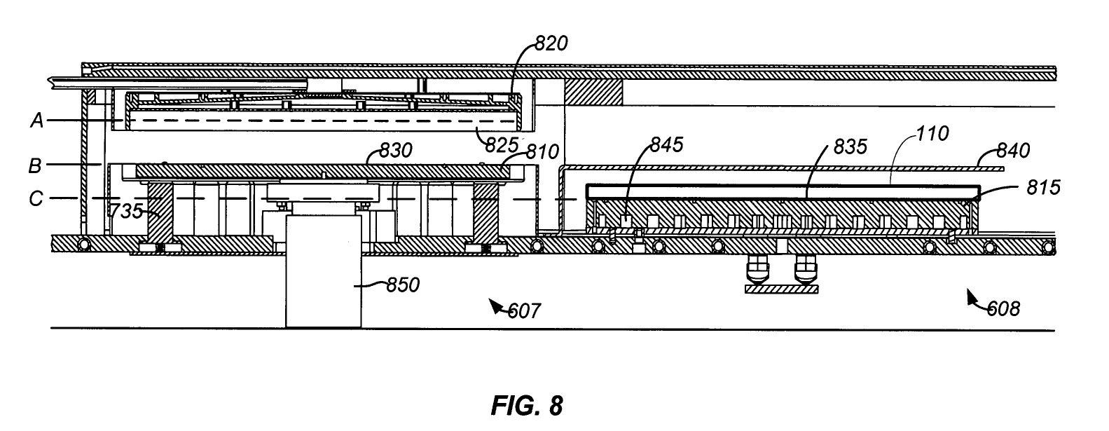

This aspect of the invention is illustrated in FIG. 8, which is a simplified cross-sectional view of a portion of integrated thermal unit 605 showing bake plate 810 and chill plate 815. As shown in FIG. 8, when bake plate 810 is within claim shell enclosure 820 at a baking position 825, wafer support surface 830 lies in a horizontal plane A that is well above the horizontal plane C that support surface 835 of chill plate 815 lies in. Also as shown in FIG. 8, the low thermal mass wafer support 110 is in direct contact with the chill plate 815 so that heat is exchanged directly between the chill plate 815 and the low thermal mass wafer support 110. The low thermal mass wafer support 110 is constructed so that it has a higher thermal conductivity in the plane parallel to the top wafer surface and bottom wafer surface than in the direction perpendicular to the top wafer surface and bottom wafer surface, as was previously discussed above. Although not shown, the low thermal mass wafer support 110 can also be positioned in direct contact with the bake plate 810. In some embodiments plane A is at least 4 cm above plane C and in one particular embodiment plane A is 6 cm above plane C. Furthermore, in some embodiments of the invention even when the bake plate is engaged with heat sinks (described below) while in a wafer receiving position, upper surface 830 of the bake plate lies in a horizontal plane B that is above the upper support surface 835 of the chill plate (plane C). In some embodiments plane B is at least 2 cm above plane C and in one particular embodiments plane B is 2.5 cm above plane C. Also, in some embodiments the upper surface of particle shield 840 also lies in or substantially closed to plane B. Chill plate 815 can further include passages 845 for delivery of coolant to the chill plate to improve cooling. Additionally, Bake plate 810 is operatively coupled to a motorized lift 850 so that the bake plate can be raised into a clam shell enclosure 820 and lowered into a wafer receiving position. Typically, wafers are heated on bake plate 810 when it is raised to a baking position 825.

Maintaining such a height difference in the positions of bake plate 810 and chill plate 815 helps minimize thermal cross-talk between the two stations and helps ensure a highly controlled, repeatable thermal treatment among multiple wafers.

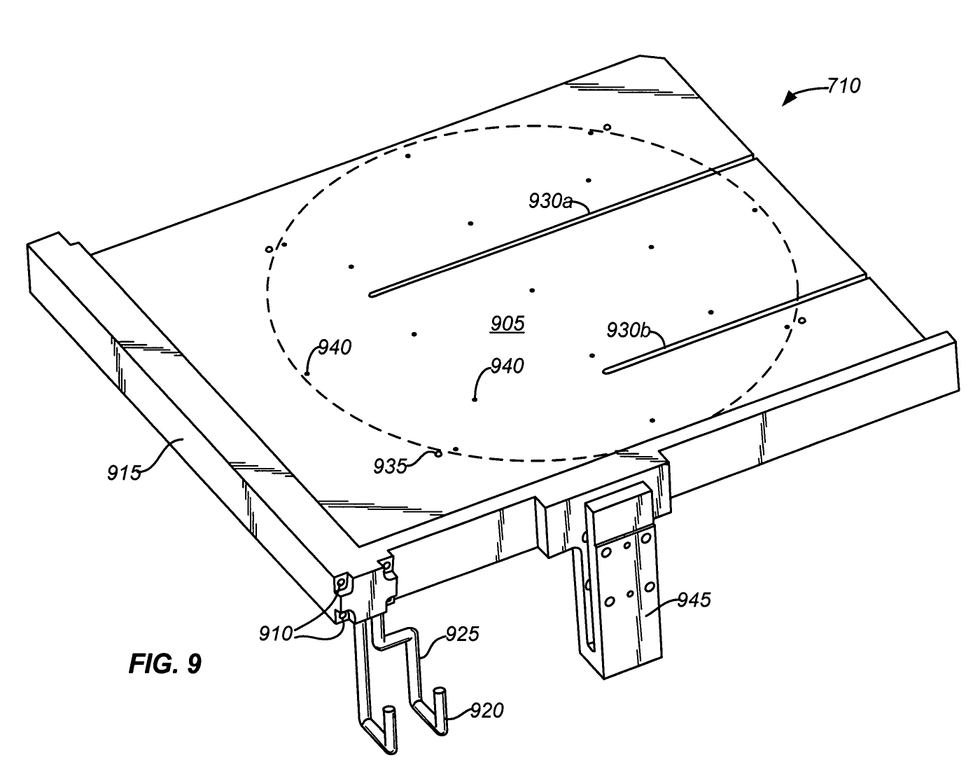

Another aspect of the present invention that helps ensure an extremely high degree of uniformity in the thermal treatment of each wafer is the design of shuttle 710. As shown in FIG. 9, which is a simplified perspective view of shuttle 710, the shuttle includes a wafer receiving area 905 upon which a semiconductor wafer is placed while the shuttle is transferring the wafer from one station to another. In one embodiment, shuttle 710 is made from aluminum and wafer receiving area 905 and other portions of an upper support surface 835 of the shuttle are actively cooled by a coolant (e.g., deionized water) that flows through coolant passages (shown in FIG. 8 as passages 845) in the shuttle.

The coolant is delivered to passages 845 by tubes that connect to inlets/outlets 910, which in turn connect to a manifold (not shown) within portion 915 of shuttle 710 that helps distribute the fluid evenly throughout the shuttle. The fluid tubes are at least partially supported by fingers 920 of tube support mechanism 925 as shuttle 710 traverses the length of the integrated thermal unit. Actively cooling wafer receiving surface 905 helps maintain precise thermal control of wafer temperature during all times while the wafer is within thermal unit 605. Actively cooling shuttle 710 also starts the wafer cooling process sooner than it would otherwise be initiated if such active cooling did not occur until the wafer is transferred to a dedicated chill station, which in turn reduces the overall thermal budget of the wafer.

Also shown in FIG. 9 are slots 930a, 930b, wafer pocket buttons 935 and small contact area proximity pins 940. Slots 930a, 930b allow the shuttle to be positioned or moved under a wafer being held by lift pins. For example, in chiller 608 a wafer is held above the chill plate prior to and after chilling on a set of three lift pins arranged in a triangular formation. Slot 930a is aligned to allow shuttle 710 to slide past two of the three lift pins and slot 930b is aligned to allow the shuttle to slide pass the third lift pin. Pocket buttons 935 screw into threaded holes in the upper surface of shuttle 710 and extend above the surface to help center a wafer within wafer receiving area 905. Pocket buttons 940 can be made from any appropriately soft material, such as a thermoplastic material, that exhibits strong fatigue resistance and thermal stability. In one embodiment, buttons 935 are made from polyetheretherketone, which is also known as PEEK.

Proximity pins 940 are distributed across upper surface 905 of shuttle 710 and are fabricated from a material with a low coefficient of friction, such as sapphire. Proximity pins 940 allow the wafer being transported by shuttle 710 to be brought into very close proximity of temperature controlled surface 905. The small space between the wafer and temperature controlled surface 905 helps create uniform cooling across the entire surface area of the wafer while at the same time minimizing contact between the underside of the wafer and the shuttle thus reducing the likelihood that particles or contaminants may be generated from such contact. Further details of proximity pins 940 are set forth in U.S. application Ser. No. 11/111,155, entitled “Purged Vacuum Chuck with Proximity Pins” filed on Apr. 20, 2005, which is hereby incorporated by reference for all purposes. In one particular embodiment shuttle 710 includes four pocket buttons 935 and seventeen proximity pins 940.

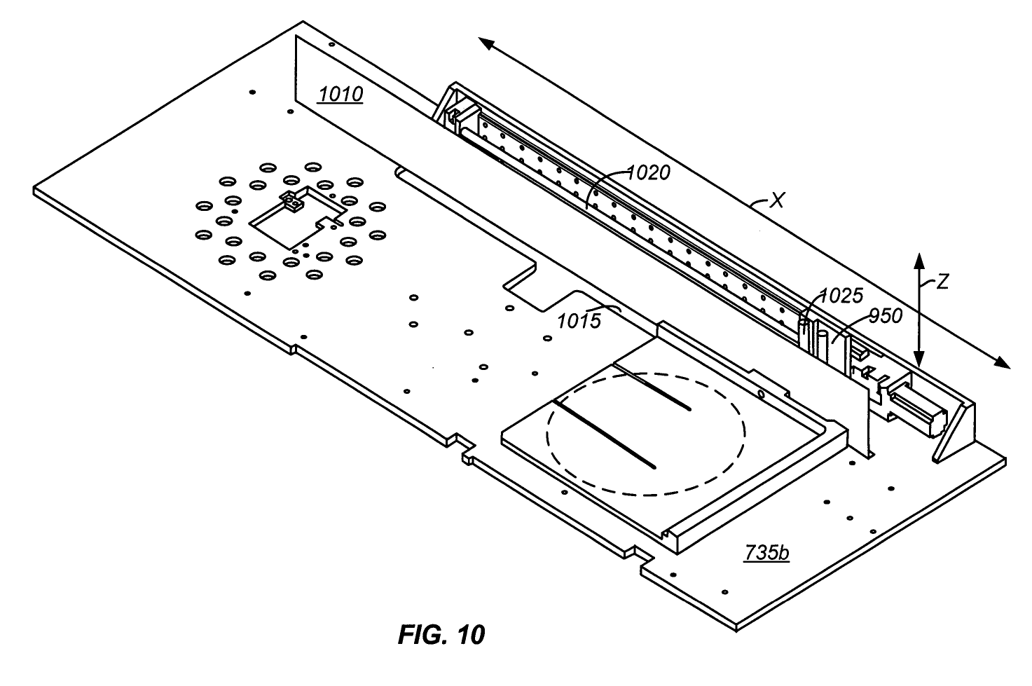

Shuttle 710 also includes an elongated U-shaped support bracket 945 that allows the shuttle to be mounted to a support plate 950 shown in FIG. 10, which is a perspective view of a portion of integrated thermal unit 605 having heater 607 and chiller 608 removed. As seen in FIG. 10, support plate 950 loops under and around rear support piece 1010, which is mounted to bottom plate 735b, through slot 1015. Plate 950 (and thus shuttle 710) can be moved linearly along a track 1020 (horizontal path X). Plate 950 also slides vertically along track 1025 allowing shuttle 710 to be raised and lowered (vertical path Z) in order to pick up and/or drop off wafers at a particular station.

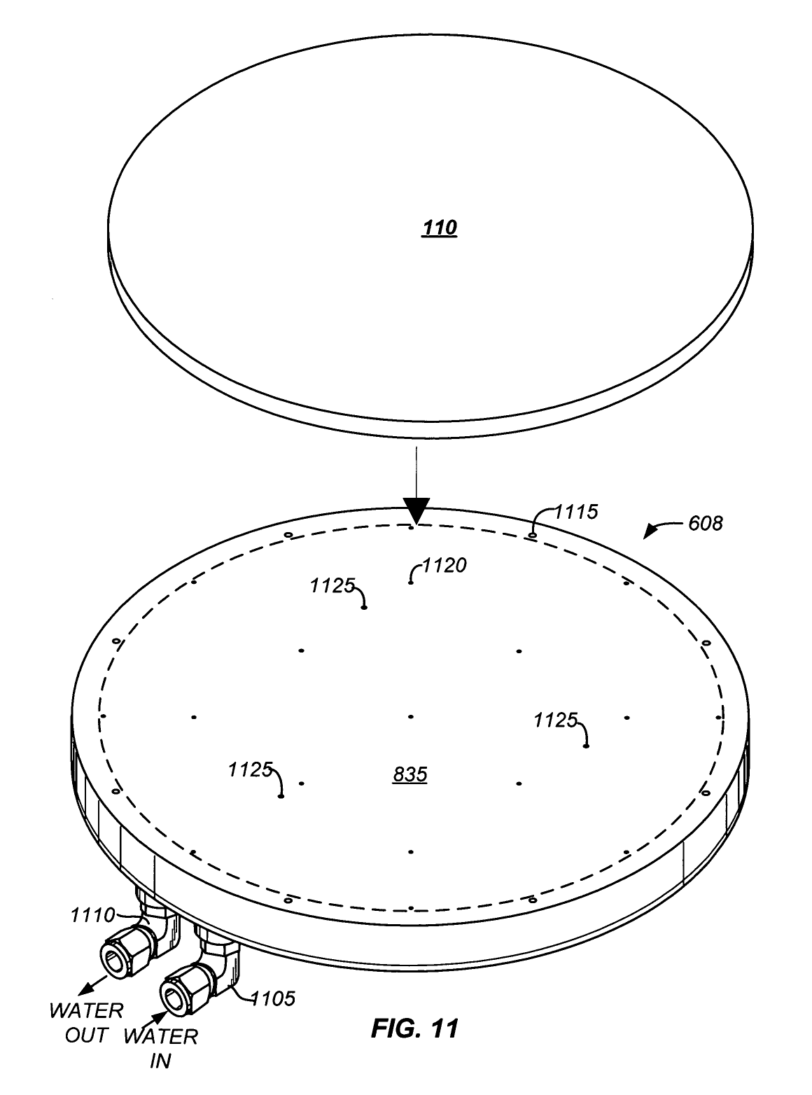

Referring now to FIG. 11, which is a perspective view of chiller 608 according to one embodiment of the invention, chiller 608 includes a coolant inlet 1105 and outlet 1110 that allow a coolant liquid, such as deionized water, to be circulated through coolant channels (not shown) to cool a wafer supported on support surface 835. Chiller 608 also includes a number of wafer pocket buttons 1115 and small contact area proximity pins 1120 that are similar to buttons 935 and proximity pins 940 described above with respect to FIG. 9. In one particular embodiment, chiller 608 includes eight pocket buttons 1115 and seventeen proximity pins 1120. Chiller 608 further includes holes 1125 that allow the lift pins to extend through chiller 608. Also, while not shown in FIG. 11, chiller 608 may include a plurality of vacuum ports and be operatively coupled to a vacuum chuck to secure a wafer to the chill plate during the cooling process. Additionally, FIG. 11 shows the low thermal mass wafer support 110 raised above the support surface 835 with an arrow showing that the low thermal mass wafer support 110 will positioned on top of the support surface 835 as was further discussed above.

Also not shown in FIG. 11, a particle shield is positioned above chiller 608 in order to protect the chill plate, and any wafer positioned on the chill plate, from possible particle contamination when shuttle 710 traverses between heater 607 and shuttle station over chiller 608. The particle shield is connected to bottom housing piece 735b between heater 607 and chiller 608 and front side piece 735a of the housing in a manner that allows shuttle 710 to pass under the particle shield and access chiller 608 as needed. In one particular embodiment, particle shield is made from stainless steel.

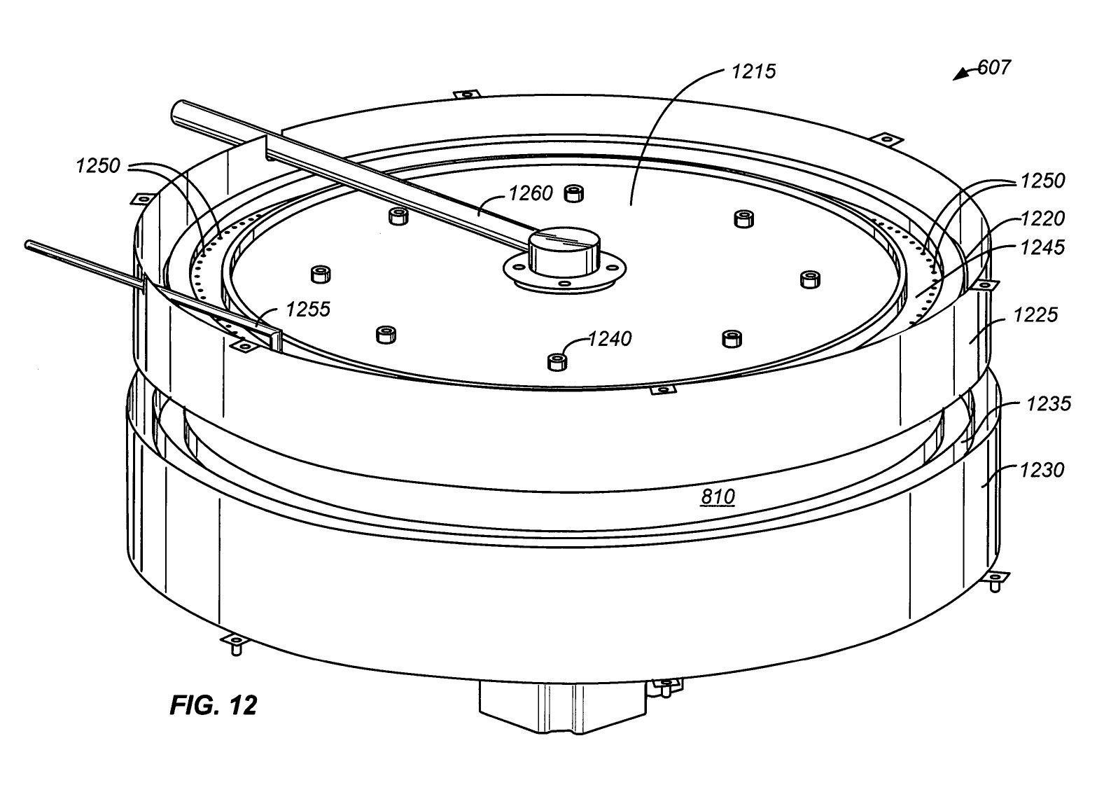

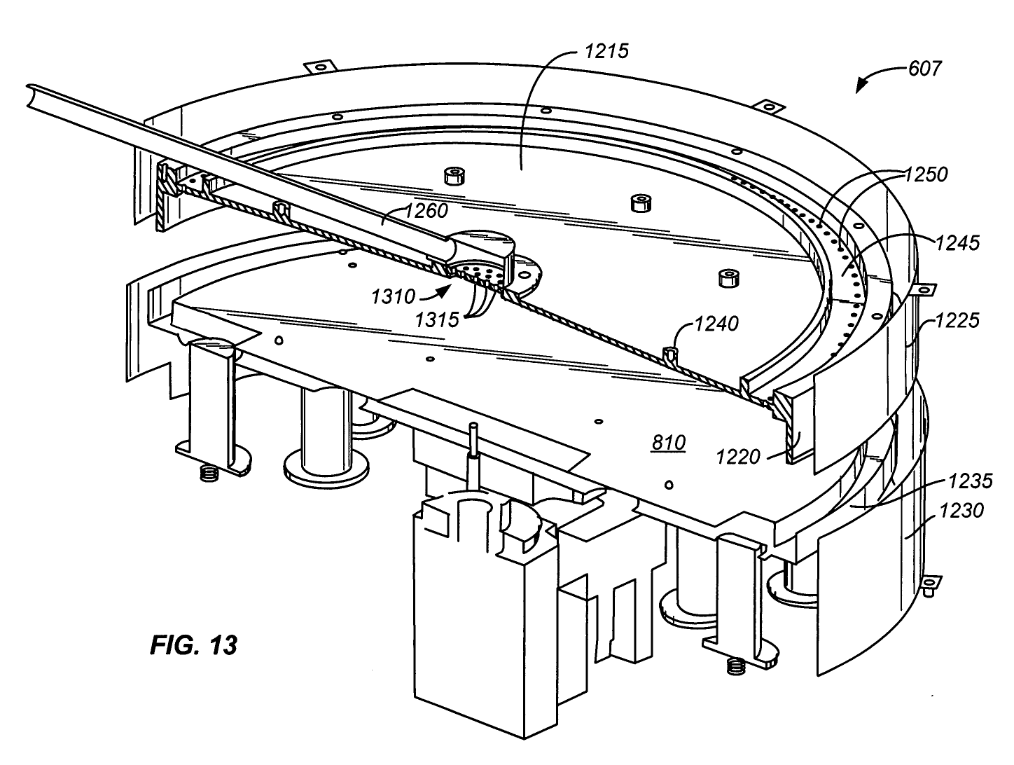

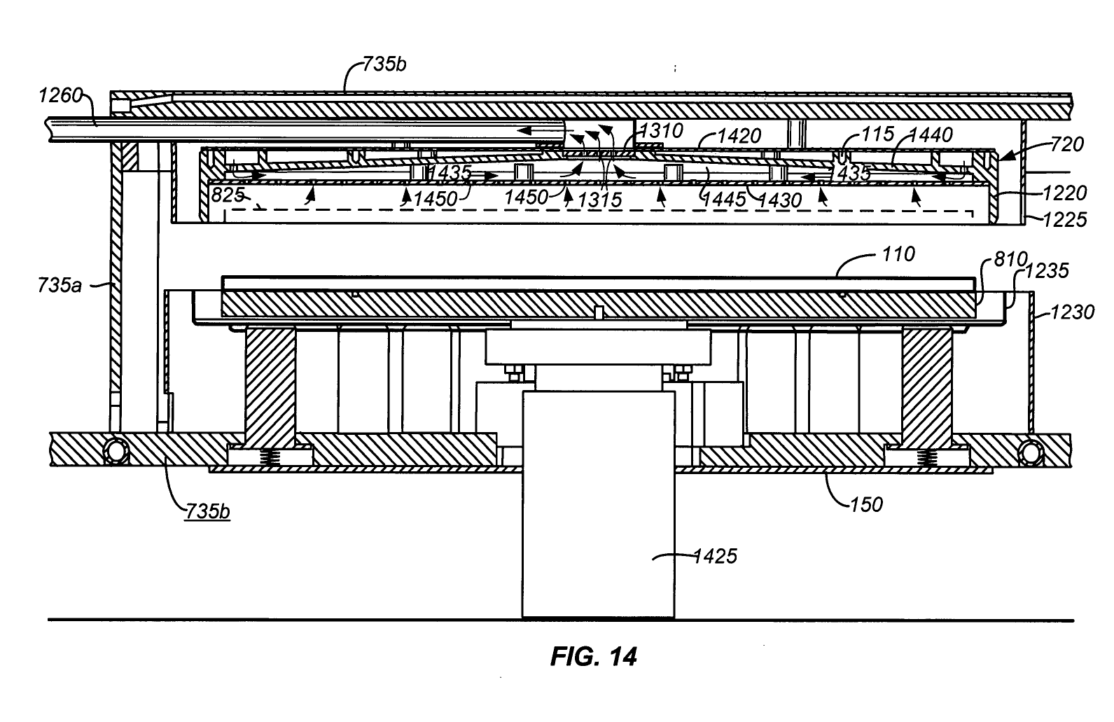

Reference is now made to FIGS. 12, 13 and 14 where FIG. 12 is a perspective view of heater 607 shown in FIG. 6 according to one embodiment of the invention; FIG. 13 is a perspective view of a cross-section of heater 607 shown in FIG. 12, and FIG. 14 is a cross-sectional view of the heater. As shown in FIGS. 12-14, heater 607 has three separate isothermal heating elements: bake plate 810, top heat plate 1215 and side heat plate 1220, each of which is manufactured from a material exhibiting high heat conductivity, such as aluminum or other appropriate material. Each plate 810, 1215, 1220 has a heating element, for example, resistive heating elements, embedded within the plate. Heater 607 also includes side top and bottom heat shields 1225 and 1230, respectively, as well as a bottom cup 1235 that surrounds bake plate 810 and a lid 1420 (shown in FIG. 14 only). Each of heat shields 1225, 1230, cup 1235 and lid 1420 are made from aluminum. Lid 1420 is attached to top heat plate 1215 by eight screws that are threaded through threaded holes 1240.

Bake plate 810 is operatively coupled to a motorized lift 1425 so that the bake plate can be raised into a clam shell enclosure 720 and lowered into a wafer receiving position. Typically, wafers are heated on bake plate 810 when it is raised to a baking position as shown in FIG. 8, position 825. When in the baking position, cup 1235 encircles a bottom portion of side heat plate 1220 forming a clam shell arrangement that helps confine heat generated by bake plate 810 within an inner cavity formed by the bake plate and enclosure 820. In one embodiment the upper surface of bake plate 810 includes 8 wafer pocket buttons and 17 proximity pins similar to those described with respect to shuttle 710 and chiller 608. Also, in one embodiment bake plate 810 includes a plurality of vacuum ports and be operatively coupled to a vacuum chuck to secure a wafer to the bake plate during the baking process.

Although the low thermal mass wafer support 110 is not shown in FIG. 13, in one embodiment of the invention the low thermal mass wafer support 110 can be positioned over bake plate 810 so that a wafer will rest on top of the low thermal mass wafer support 110. In this embodiment the low thermal mass wafer support 110 may have small holes or slots in it to allow pins through to easily remove the wafer with a shuttle. FIG. 14, however, does show the low thermal mass wafer support 110 positioned over the bake plate 810 in accordance with one embodiment of the invention. In this embodiment, the low thermal mass wafer support 110 is in direct contact with the bake plate and the optional holes for pins to assist with removing wafers are not shown.

During the baking process, a faceplate 1430 shown in FIG. 14 is positioned just above and opposite wafer support surface 830 of bake plate 810. The faceplate 1430 can be made from aluminum as well as other suitable materials and includes a plurality of holes or channels 1450 that allow gases and contaminants baked off the surface of a wafer being baked on bake plate 810 to drift through the faceplate 1430 and into a radially inward gas flow 1435 that is created between the faceplate 1430 and top heat plate 1440.

Gas from radially inward gas flow 1435 is initially introduced into heater 607 at an annular gas manifold 1245 that encircles the outer portion of top heat plate 1215 by a gas inlet line 1255. Gas manifold 1245 includes numerous small gas inlets 1250 (128 inlets in one embodiment) that allow gas to flow from manifold 1245 into the cavity 1445 between the lower surface of top heat plate 1215 and the upper surface of faceplate 1430. The gas flows radially inward towards the center of the station through a diffusion plate 1310 that includes a plurality of gas outlet holes 1315. After flowing through diffusion plate 1310, gas exits heater 607 through gas outlet line 1260.

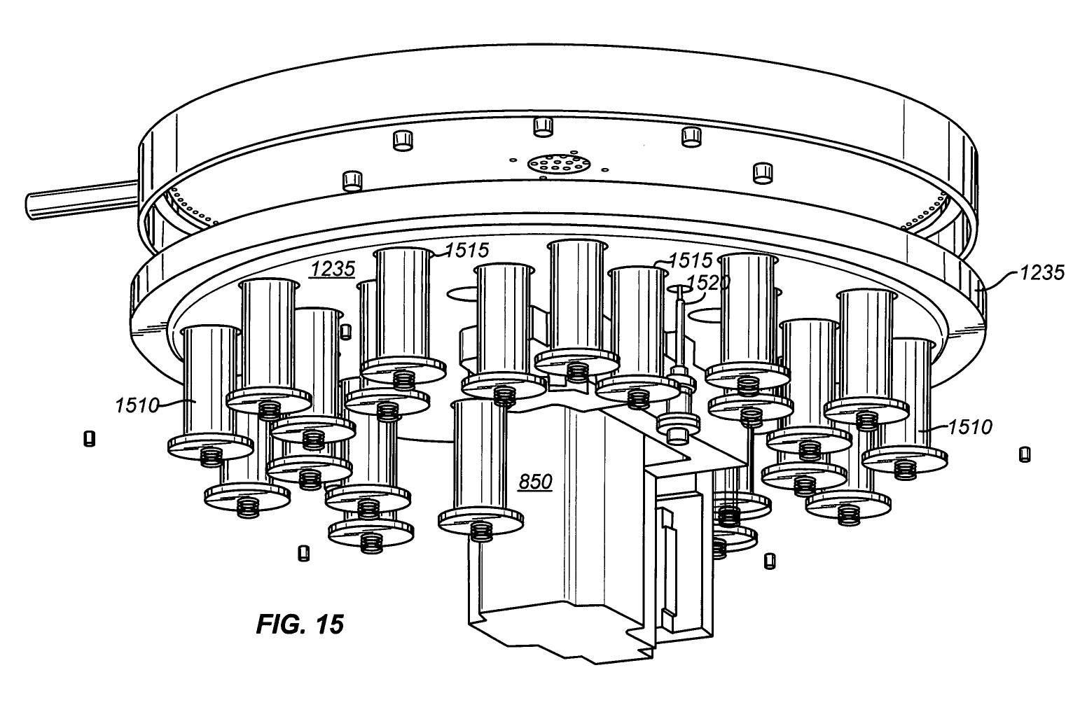

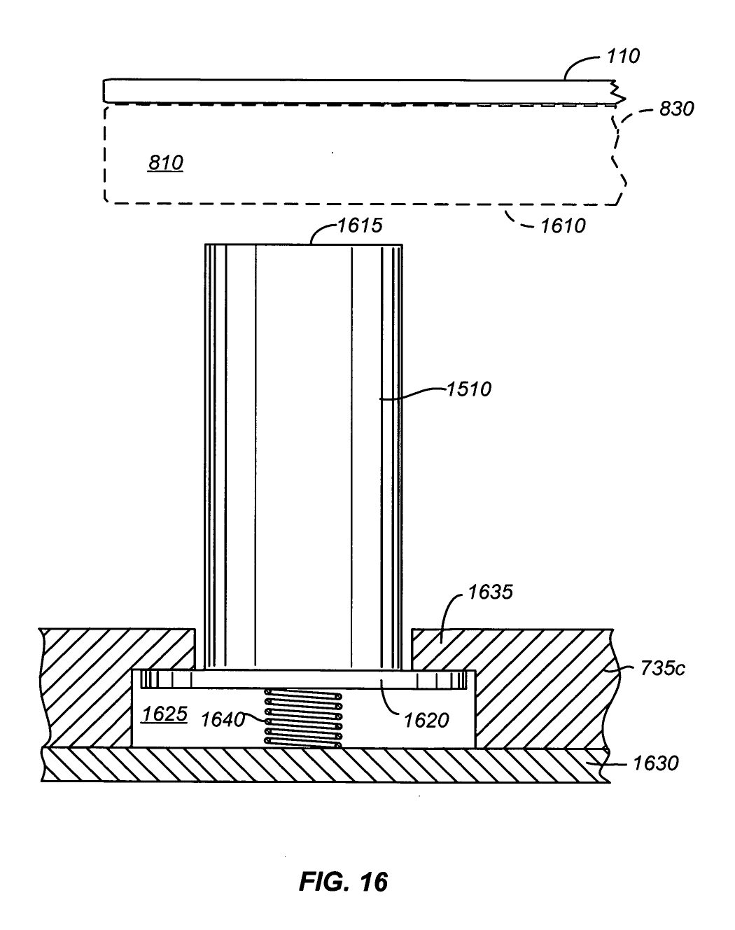

An aspect of the invention that helps minimize any delay associated with switching from one thermal recipe to another thermal recipe an thus helps ensure high wafer throughput through integrated thermal unit 605 is discussed below with respect to FIGS. 15 and 16. FIG. 15 is a bottom perspective view of heater 607 shown FIGS. 12-14. As shown in FIG. 15, in one embodiment of the invention heater 607 includes a plurality of engageable heat sinks 1510. Each engageable heat sink 1510 is made from an appropriate heat sink material, such as aluminum, copper, stainless steel or other metal.

As previously mentioned, bake plate 810 heats a wafer according to a particular thermal recipe. One component of the thermal recipe is typically a set point temperature at which the bake plate is set to heat the wafer. During the baking process, the temperature of the wafer is routinely measured and one or more zones of the bake plate can be adjusted to ensure uniform heating of the substrate. Typically bake plate is heated to the desired set point temperature while a large batch of wafers is processed according to the same thermal recipe. Thus, for example, if a particular thermal recipe calls for a set point temperature of 175° C. and that recipe is to be implemented on 100 consecutive wafers, bake plate 810 will be heated to 175° C. during the length of time it takes to process the 100 consecutive wafers. If, however, a subsequent batch of 200 wafers is to be processed according to a different thermal recipe that, for example, requires a set point temperature of 130° C., the set point temperature of bake plate 810 needs to be rapidly changed from 175° C. to 130° C. between processing the 100th and 101st wafers.

Embodiments of the present invention enable a rapid reduction in the set point temperature of bake plate 810 by lowering the bake plate with motor 850 into a lower cooling position that is below the wafer receiving position. In the cooling position a bottom surface 1610 of the bake plate contacts an upper surface 1615 of each heat sink 1510. Contact between the heat sinks and bake plate is possible because bottom cup 1235 includes a plurality of holes 1515 that correspond to the plurality of heat sinks 1510 allowing the heat sinks to extend through bottom cup 1235 to contact bake plate 810.

FIG. 16 is a simplified cross-sectional view of an engageable heat sink 1510. As shown in FIG. 16, each engageable heat sink 1510 includes a lower base portion 1620 that has a larger diameter than the main body of the heat sink. Lower base portion 1620 fits within a cavity 1625 that is defined by bottom base plate 735c and an aluminum plate 1630. Base portion 1620 of the heat sink engages a lip 1635 of the bottom base plate and is pressed against the lip by a spring 1640 positioned between aluminum plate 1630 and base portion 1620.

When bake plate 810 is lowered into the cooling position, spring 1640 causes heat sink 1510 to press upon lower surface of 1610 of the bake plate. The combined thermal mass of all heat sinks 1510 allows bake plate 810 to be rapidly cooled from one set point temperature to a lower set point temperature as may be required, for example, when transitioning to a new thermal recipe. Since the support surface 830 of bake plate 810 is connected to the low thermal mass wafer support 110, any wafer resting on the low thermal mass wafer support 110 will also cool rapidly when the heat sink is engaged.

While heat sink 1510 shown in FIGS. 15 and 16 is shown to be cylindrical in shape, many other shapes and sizes can be used. Also, in some embodiments, each heat sink 1510 can be actively cooled by forming one or more coolant channels within the body of the heat sink. Also in some embodiments, heat sink 1510 includes a thermal pad on its upper surface 1615 that provides for smooth contact between the heat sink and bake plate during the engaging process.

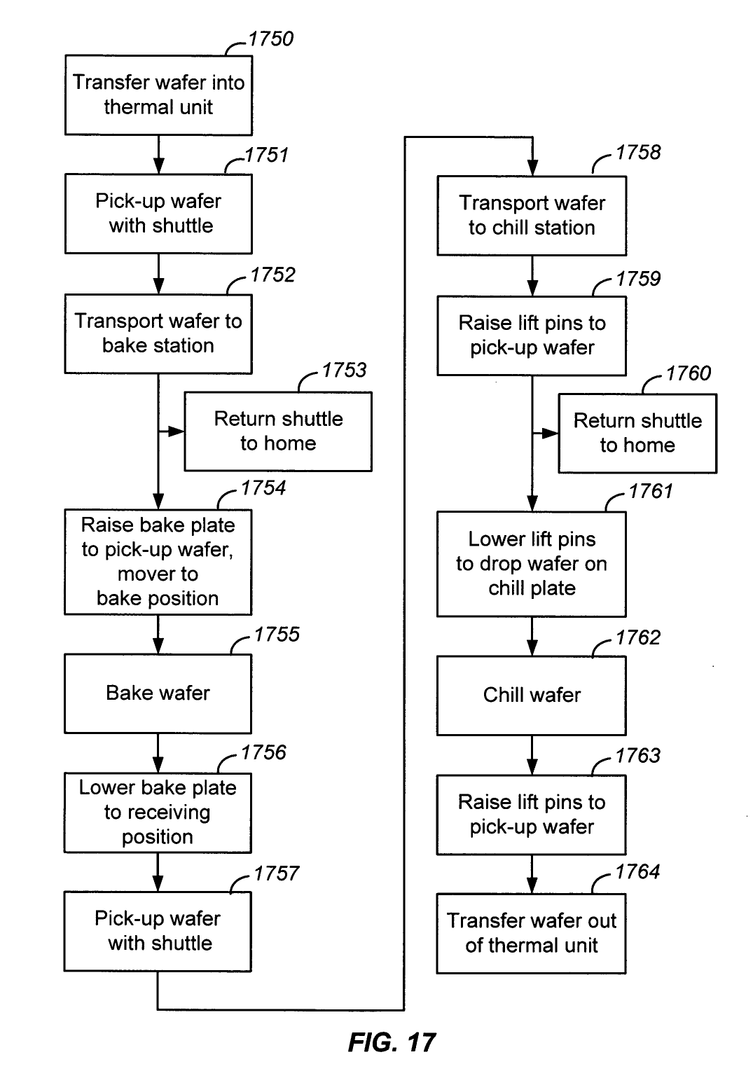

In order to better appreciate and understand the general operation of integrated thermal unit 605, reference is now made to FIG. 17 along with FIGS. 6 and 7. FIG. 17 is a simplified block diagram that illustrates a sequence of events that is performed by thermal unit 605 to thermally treat wafers according to one embodiment of the method of the present invention. A wafer may be treated in accordance with the process set forth in FIG. 17 after, for example, having a photoresist layer deposited over the wafer at an appropriate coating station of a track lithography tool. While the discussion below focuses on treating a single wafer within unit 605, a person of skill in the art will appreciate that thermal unit 605 will often be used to simultaneously process two wafers. For example, while one wafer is being heated on bake plate 810, thermal unit 605 can be in the process of cooling another wafer on chill plate 715 or transferring another wafer out of the thermal unit at the completion of its thermal treatment.

As shown in FIG. 17, a wafer's history in thermal unit 605 starts by transferring the wafer into the thermal unit 605 through second wafer transfer slot 740b and placing the wafer into the shuttle 710 of the integrated thermal unit 605 (FIG. 17, step 1750). The wafer may be transferred into thermal unit 605 by, for example, a central robot that services both wafer transfer slots 740a and 740b as well as one or more coating or developing stations in a track lithography tool (not shown). Typically wafer transfer slot 740b is closed by a shutter, thus step 1750 also includes moving a shutter to open slot 740b. During step 1750 chill shuttle 710 is in a wafer receiving position where lift pins extend through slots 745a and 745b of the shuttle 710. After the wafer is properly positioned on lift pins, the robot arm recedes out of the thermal unit and chill shuttle 710 is raised to lift the wafer off of stationary lift pins (FIG. 17, step 1751) and then moved linearly along the length of the thermal unit to transfer the wafer to heater 607 (FIG. 17, step 1752). The path to heater 607 takes shuttle 710 over a particle shield at chiller 608.

At heater 607, the wafer is placed on lift pins and shuttle 710 is free to handle another task or return to its home position at shuttle station (FIG. 17, step 1753). While the shuttle is being returned to home position, bake plate 810 is raised by a motorized lift thereby picking the wafer up off of stationary lift pins and bringing the wafer into its bake position within clam shell enclosure 720 (FIG. 17, step 1754). Once inside claim shell enclosure 720 the wafer is heated or baked according to a desired thermal recipe (FIG. 17, step 1755).

After completion of bake step 1755, the bake plate 810 is lowered to its wafer receiving position dropping the wafer off on lift pins (FIG. 17, step 1756). Next, shuttle 710 returns to heater 607 and picks the wafer up off of lift pins (FIG. 17, step 1757) and brings the wafer to chiller 608 (FIG. 17, step 1758). The path to chiller 608 takes shuttle over the particle shield to the shuttle station where shuttle 710 is lowered and then moved towards chiller 608. Once at chiller 608, the lift pins are raised by a pneumatic lift, to lift the wafer off of the shuttle (FIG. 17, step 1759). Shuttle 710 is then free to handle another task or return to its home position (FIG. 17, step 1760) and the lift pins are lowered to drop the wafer of onto chill plate 715 (FIG. 17, step 1761).

The wafer is then cooled on chill plate 715 according to a predetermined thermal recipe (FIG. 17, step 1762). After completion of the cooling process, the lift pins are raised to pick the wafer up off of the chill plate (FIG. 17, step 1763) and the wafer is transferred out of the integrated thermal unit through elongated slot 740a (FIG. 17, step 1764) by, for example, being picked up by the same central robot that transferred the wafer into the thermal unit in step 1750. Typically, elongated slot 740a is closed by a shutter, thus step 1764 also includes opening the shutter to open slot 740a.

Embodiments of the invention allow a process such as that described above to be carried out in a highly controllable and highly repeatable manner. Thus, embodiments of the invention help ensure an extremely high degree of uniformity in the thermal treatment of each wafer that is processed within integrated thermal unit 10 according to a particular thermal recipe. As discussed in more detail below, a number of specific aspects of the present invention can be used independent from each other or in combination to help achieve such a repeatable, uniform wafer history.

One such aspect is the placement of hot plate 810 with respect to chill plate 715. Specifically, in some embodiments of the invention hot plate 810 is positioned within integrated thermal unit 605 at a position that is higher than the position of chill plate 715. Because heat generated from bake plate 810 generally rises to an upper portion of thermal unit 605, such positioning helps minimize thermal cross-talk between the heater 607 and chiller 608 that may otherwise lead to discrepancies in the thermal treatment of wafers over time.

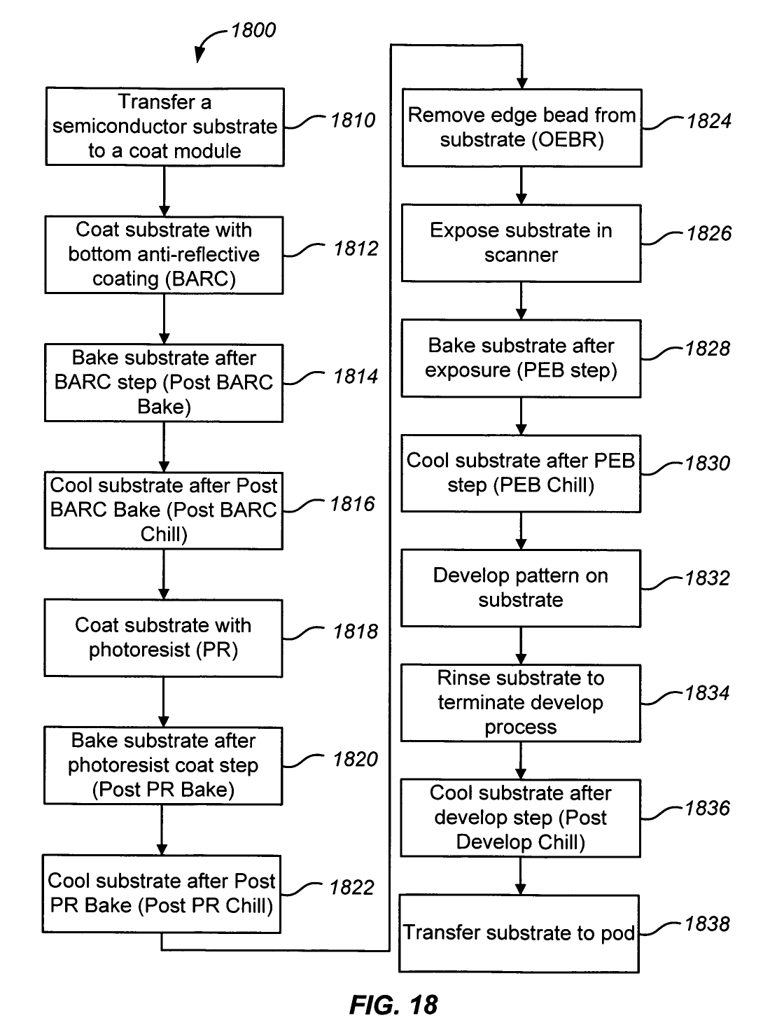

FIG. 18 illustrates one embodiment of a series of method steps 1800 that may be used to deposit, expose and develop a photoresist material layer formed on a substrate surface. The lithographic process may generally contain the following: a transfer substrate to coat module step 1810, a bottom anti-reflective coating (BARC) coat step 1812, a post BARC bake step 1814, a post BARC chill step 1816, a photoresist coat step 1818, a post photoresist bake step 1820, a post photoresist chill step 1822, an optical edge bead removal (OEBR) step 1824, an exposure step 1826, a post exposure bake (PEB) step 1828, a post exposure bake chill step 1830, a develop step 1832, a substrate rinse step 1834, a post develop chill step 1836 and a transfer substrate to pod step 1838. In other embodiments, the sequence of the method steps 1800 may be rearranged, altered, one or more steps may be removed, additional steps added or two or more steps may be combined into a single step with out varying from the basic scope of the invention.

In step 1810, a semiconductor substrate is transferred to a coat module. Referring to FIG. 6, the step of transferring the substrate to the coat module is generally defined as the process of having front end robot 618 remove a substrate from a cassette 630 resting in one of the pod assemblies 616. A cassette 630, containing one or more substrates “W”, is placed on the pod assembly 616 by the user or some external device (not shown) so that the substrates can be processed in the cluster tool 600 by a user-defined substrate processing sequence controlled by software retained in the system controller 640.

The BARC coat step 1812 is a step used to deposit an organic material over a surface of the substrate. The BARC layer is typically an organic coating that is applied onto the substrate prior to the photoresist layer to absorb light that otherwise would be reflected from the surface of the substrate back into the resist during the exposure step 1826 performed in the stepper/scanner 602. If these reflections are not prevented, standing waves will be established in the resist layer, which cause feature size to vary from one location to another depending on the local thickness of the resist layer. The BARC layer may also be used to level (or planarize) the substrate surface topography, which is generally present after completing multiple electronic device fabrication steps. The BARC material fills around and over the features to create a flatter surface for photoresist application and reduces local variations in resist thickness.

BARC coat step 1812 is typically performed using a conventional spin-on resist dispense process in which an amount of the BARC material is deposited on the surface of the substrate while the substrate is being rotated which causes a solvent in the BARC material to evaporate and thus causes the material properties of the deposited BARC material to change. The air flow and exhaust flow rate in the BARC processing chamber is often controlled to control the solvent vaporization process and the properties of the layer formed on the substrate surface.

Post BARC bake step 1814, is a step used to assure that all of the solvent is removed from the deposited BARC layer in BARC coat step 1812, and in some cases to promote adhesion of the BARC layer to the surface of the substrate. The temperature of post BARC bake step 1814 is dependent on the type of BARC material deposited on the surface of the substrate, but will generally be less than about 250° C. The time required to complete post BARC bake step 1814 will depend on the temperature of the substrate during the post BARC bake step, but will generally be less than about 60 seconds.

Post BARC chill step 1816, is a step used to control and assure that the time the substrate is above ambient temperature is consistent so that every substrate sees the same time-temperature profile and thus process variability is minimized. Variations in the BARC process time-temperature profile, which is a component of a substrates wafer history, can have an effect on the properties of the deposited film layer and thus is often controlled to minimize process variability. Post BARC chill step 1816, is typically used to cool the substrate after post BARC bake step 1814 to a temperature at or near ambient temperature. The time required to complete post BARC chill step 1816 will depend on the temperature of the substrate exiting the post BARC bake step, but will generally be less than about 30 seconds.

Photoresist coat step 1818, is a step used to deposit a photoresist layer over a surface of the substrate. The photoresist layer deposited during the photoresist coat step 1818 is typically a light sensitive organic coating that is applied onto the substrate and is later exposed in the stepper/scanner 602 to form the patterned features on the surface of the substrate. Photoresist coat step 1818 is a typically performed using conventional spin-on resist dispense process in which an amount of the photoresist material is deposited on the surface of the substrate while the substrate is being rotated which causes a solvent in the photoresist material to evaporate and thus causes the material properties of the deposited photoresist layer to change. The air flow and exhaust flow rate in the photoresist processing chamber is controlled to control the solvent vaporization process and the properties of the layer formed on the substrate surface. In some cases it may be necessary to control the partial pressure of the solvent over the substrate surface to control the vaporization of the solvent from the resist during the photoresist coat step by controlling the exhaust flow rate and/or by injecting a solvent near the substrate surface. Referring to FIG. 6, in an exemplary photoresist coating process, the substrate is first positioned on a wafer chuck in coater/developer module 634. A motor rotates the wafer chuck and substrate while the photoresist is dispensed onto the center of the substrate. The rotation imparts an angular torque onto the photoresist, which forces the photoresist out in a radial direction, to ultimately covering the substrate.

Photoresist bake step 1820, is a step used to assure that all of the solvent is removed from the deposited photoresist layer in photoresist coat step 1818, and in some cases to promote adhesion of the photoresist layer to the BARC layer. The temperature of post photoresist bake step 1820 is dependent on the type of photoresist material deposited on the surface of the substrate, but will generally be less than about 350° C. The time required to complete post photoresist bake step 1820 will depend on the temperature of the substrate during the post photoresist bake step, but will generally be less than about 60 seconds.

Post photoresist chill step 1822 is a step used to control the time the substrate is at a temperature above ambient temperature so that every substrate sees the same time-temperature profile and thus process variability is minimized. Variations in the time-temperature profile can have an effect on properties of the deposited film layer and thus is often controlled to minimize process variability. The temperature of post photoresist chill step 1822 is thus used to cool the substrate after post photoresist bake step 1820 to a temperature at or near ambient temperature. The time required to complete post photoresist chill step 1822 will depend on the temperature of the substrate exiting the post photoresist bake step, but will generally be less than about 30 seconds.

Optical edge bead removal (OEBR) step 1824, is a process used to expose the deposited light sensitive photoresist layer(s), such as, the layers formed during photoresist coat step 1818 and the BARC layer formed during BARC coat step 1812, to a radiation source (not shown) so that either or both layers can be removed from the edge of the substrate and the edge exclusion of the deposited layers can be more uniformly controlled. The wavelength and intensity of the radiation used to expose the surface of the substrate will depend on the type of BARC and photoresist layers deposited on the surface of the substrate. An OEBR tool can be purchased, for example, from USHIO America, Inc. Cypress, Calif.

Exposure step 1826 is a lithographic projection step applied by a lithographic projection apparatus (e.g., stepper scanner 602) to form a pattern which is used to manufacture integrated circuits (ICs). The exposure step 1826 forms a circuit pattern corresponding to an individual layer of the integrated circuit (IC) device on the substrate surface, by exposing the photosensitive materials, such as, the photoresist layer formed during photoresist coat step 1818 and the BARC layer formed during the BARC coat step 1812 of some form of electromagnetic radiation.

Post exposure bake (PEB) step 1828 is a step used to heat a substrate immediately after exposure step 1826 in order to stimulate diffusion of the photoactive compound(s) and reduce the effects of standing waves in the resist layer. For a chemically amplified resist, the PEB step also causes a catalyzed chemical reaction that changes the solubility of the resist. The control of the temperature during the PEB is typically critical to critical dimension (CD) control. The temperature of PEB step 1828 is dependent on the type of photoresist material deposited on the surface of the substrate, but will generally be less than about 250° C. The time required to complete PEB step 1828 will depend on the temperature of the substrate during the PEB step, but will generally be less than about 60 seconds.

Post exposure bake (PEB) chill step 1830 is a step used to control the assure that the time the substrate is at a temperature above ambient temperature is controlled so that every substrate sees the same time-temperature profile and thus process variability is minimized. Variations in the PEB process time-temperature profile can have an effect on properties of the deposited film layer and thus is often controlled to minimize process variability. The temperature of PEB chill step 1830 is thus used to cool the substrate after PEB step 1828 to a temperature at or near ambient temperature. The time required to complete PEB chill step 1830 will depend on the temperature of the substrate exiting the PEB step, but will generally be less than about 30 seconds.

Develop step 1832 is a process in which a solvent is used to cause a chemical or physical change to the exposed or unexposed photoresist and BARC layers to expose the pattern formed during exposure process step 1826. The develop process may be a spray or immersion or puddle type process that is used to dispense the developer solvent. In some develop processes, the substrate is coated with a fluid layer, typically deionized water, prior to application of the developer solution and spun during the development process. Subsequent application of the developer solution results in uniform coating of the developer on the substrate surface. In step 1834, a rinse solution is provided to surface of the substrate, terminating the develop process. Merely by way of example, the rinse solution may be deionized water. In alternative embodiments, a rinse solution of deionized water combined with a surfactant is provided. One of ordinary skill in the art would recognize many variations, modifications, and alternatives.

In step 1836 the substrate is cooled after the develop and rinse steps 1832 and 1834. In step 1838, the substrate is transferred to the pod, thus completing the processing sequence. Transferring the substrate to the pod in step 1838 generally entails the process of having the front end robot 618 return the substrate to a cassette 630 resting in one of the pod assemblies 616.

Based on the description of the present invention herein, a person of skill in the art will appreciate that embodiments of the invention may be beneficially used to heat and/or cool a substrate during, among other steps not described in FIG. 18, post BARC bake step 1814 and post BARC chill step 1816, during post PR bake step 1820 and post PR chill step 1822, during post exposure bake step 1828 and post exposure chill step 1830 and during post develop chill step 1836. A skilled artisan will also appreciate some of the various bake and chill sequences set just described have differing bake and or chill requirements. Thus, the skilled artisan will appreciate that the functional specifications of a particular bake plate 810 and/or chill plate 715 incorporated into the integrated thermal unit 605 will depend on the material the bake and/or chill plate are intended to heat and cool, respectively. For example, BARC materials may be adequately heated with a low temperature, low precision bake plate (e.g., a maximum 250° C., single zone heater) while photoresist materials may require a high temperature, mid-precision bake plate (e.g., a maximum 350° C., three zone heater) and the post exposure bake process may require a low temperature, high precision bake plate (e.g., a maximum 250° C., fifteen zone heater). Thus, embodiments of the invention are not limited to any particular type of or configuration of bake plate 810 or chill plate 715. Instead, generally each of bake plate 810 and chill plate 715 is designed to particular performance standards as required by the application for which the bake plate and chill plate will be used as can be determined by a person of skill in the art.

While the present invention has been described with respect to particular embodiments and specific examples thereof, it should be understood that other embodiments may fall within the spirit and scope of the invention. The scope of the invention should, therefore, be determined with reference to the appended claims along with their full scope of equivalents.

What is claimed is:

1. A system for chilling wafers, comprising:
a low thermal mass wafer support for providing support to a bottom surface of a wafer;
a chill plate coupled to said low thermal mass wafer support for cooling said wafer; and
wherein said low thermal mass wafer support has a higher thermal conductivity in the plane parallel to said bottom surface of the wafer than in the direction perpendicular to said bottom surface of the wafer.

2. The system of claim 1 wherein said thermal conductivity of said low thermal mass wafer support is 10 times greater in the plane parallel to said bottom surface of the wafer than in the direction perpendicular to said bottom surface of the wafer.

3. The system of claim 1 wherein said thermal conductivity of said low thermal mass wafer support is 100 times greater in the plane parallel to said bottom surface of the wafer than in the direction perpendicular to said bottom surface of the wafer.

4. The system of claim 1 wherein said low thermal mass wafer support is made of a carbon composite.

5. The system of claim 1 wherein said low thermal mass wafer support is a heat pipe comprising fluid.

6. The system of claim 1 wherein said low thermal mass wafer support has a thickness of less than 2 mm.

7. The system of claim 1 wherein said low thermal mass wafer support has a thickness of less than 1.2 mm.

8. The system of claim 1 wherein said low thermal mass wafer support has a coefficient of thermal expansion that is less than the coefficient of thermal expansion of said wafer.

9. The system of claim 1 wherein said low thermal mass wafer support is in direct contact with said chill plate.

10. The system of claim 1 further comprising:
support pins that separate said low thermal mass wafer support from said chill plate; and
exchange gas for providing a thermal link between said low thermal wafer support and said chill plate.

11. A system for chilling wafers, comprising:
a low thermal mass wafer support for providing support to a bottom surface of a wafer;
a chill plate coupled to said low thermal mass wafer support for cooling said wafer;
wherein said low thermal mass wafer support has a higher thermal conductivity in the plane parallel to said bottom surface of the wafer than in the direction perpendicular to said bottom surface of the wafer; and
wherein said low thermal mass wafer support further comprises a plurality of proximity pins for supporting said wafer.

12. The system of claim 11 wherein said proximity pins protrude about 30 to 100 microns above a surface of said low thermal mass wafer support.

13. The system of claim 11 wherein said proximity pins protrude about 30 to 70 microns above a surface of said low thermal mass wafer support.

14. The system of claim 11 wherein said proximity pins are spheres that are partially embedded in said low thermal mass wafer support.

15. The system of claim 11 wherein said proximity pins are spheres made of sapphire.

16. The system of claim 11 wherein said proximity pins are uniformly distributed over the surface of said low thermal mass wafer support.

17. The system of claim 11 wherein said plurality proximity pins are at least three proximity pins.

18. A system for heating wafers, comprising:
a low thermal mass wafer support for providing support to a bottom surface of a wafer;
a heat plate coupled to said low thermal mass wafer support for heating said wafer; and
wherein said low thermal mass wafer support has a higher thermal conductivity in the plane parallel to said bottom surface of the wafer than in the direction perpendicular to said bottom surface of the wafer.

19. The system of claim 18 wherein said thermal conductivity of said low thermal mass wafer support is 10 times greater in the plane parallel to said bottom surface of the wafer than in the direction perpendicular to said bottom surface of the wafer.

20. The system of claim 18 wherein said thermal conductivity of said low thermal mass wafer support is 100 times greater in the plane parallel to said bottom surface of the wafer than in the direction perpendicular to said bottom surface of the wafer.

21. The system of claim 18 wherein said low thermal mass wafer support is made of a carbon composite.

22. The system of claim 18 wherein said low thermal mass wafer support is a heat pipe comprising fluid.

23. A system for chilling wafers, comprising:
a chill plate for cooling a wafer;
a low thermal mass wafer support for supporting said wafer while said wafer is cooled with said chill plate, said low thermal wafer support further comprising at least one resistive element to heat said wafer and to provide an electrostatic force to said wafer during heating;
a bendable support positioned between said low thermal mass wafer support and said chill plate for regulating motion generated by activation of said electrostatic chuck;
wherein said low thermal mass wafer support has a higher thermal conductivity in the plane parallel to said bottom surface of the wafer than in the direction perpendicular to said bottom surface of the wafer; and
wherein said low thermal mass wafer support further comprises a plurality of proximity pins for supporting said wafer.

24. An integrated system for baking and chilling wafers, comprising:
a heater for heating a wafer to an elevated temperature;
a chiller for cooling said wafer;
a shuttle operatively connected to said heater and said chiller for transferring said wafer between said heater and said chiller;
wherein said chiller further comprises:
a low thermal mass wafer support for providing support to a bottom surface of a wafer;
a chill plate coupled to said low thermal mass wafer support for cooling said wafer; and
wherein said low thermal mass wafer support has a higher thermal conductivity in the plane parallel to said bottom surface of the wafer than in the direction perpendicular to said bottom surface of the wafer.

25. The integrated system of claim 24 wherein said low thermal mass wafer support further comprises a plurality of proximity pins for supporting said wafer.

26. An integrated system for baking and chilling wafers, comprising:
a heater for heating a wafer to an elevated temperature;
a chiller for cooling said wafer;
a shuttle operatively connected to said heater and said chiller for transferring said wafer between said heater and said chiller;
wherein said heater further comprises:
a low thermal mass wafer support for providing support to a bottom surface of a wafer;
a heat plate coupled to said low thermal mass wafer support for supporting said low thermal mass wafer support and for heating said wafer; and
wherein said low thermal mass wafer support has a higher thermal conductivity in the plane parallel to said bottom surface of the wafer than in the direction perpendicular to said bottom surface of the wafer.

27. The integrated system of claim 26 wherein said low thermal mass wafer support further comprises a plurality of proximity pins for supporting said wafer.

28. An integrated system for baking and chilling wafers, comprising:
a heater for heating a wafer to an elevated temperature;
a chiller for cooling said wafer;
a shuttle operatively connected to said heater and said chiller for transferring said wafer between said heater and said chiller;
wherein said heater further comprises:
a first low thermal mass wafer support for providing support to a bottom surface of a wafer;
a heat plate coupled to said first low thermal mass wafer support for supporting said first low thermal mass wafer support and for heating said wafer; and
wherein said first low thermal mass wafer support has a higher thermal conductivity in the plane parallel to said bottom surface of the wafer than in the direction perpendicular to said bottom surface of the wafer; and
wherein said chiller further comprises:
a second low thermal mass wafer support for providing support to a bottom surface of a wafer;
a chill plate coupled to said second low thermal mass wafer support for supporting said second low thermal mass wafer support and for cooling said wafer; and
wherein said second low thermal mass wafer support has a higher thermal conductivity in the plane parallel to said bottom surface of the wafer than in the direction perpendicular to said bottom surface of the wafer.

29. The integrated system of claim 28 wherein said first low thermal mass wafer support further comprises a first plurality of proximity pins for supporting said wafer and said second low thermal mass wafer support further comprises a second plurality of proximity pins for supporting said wafer.
